(19) United States
(12) Patent Application Publication
(10) Pub. No.: US 2025/0212463 A1
(43) Pub. Date: Jun. 26, 2025

(54) METAL-ALL-AROUND CONTACT STRUCTURE COUPLED WITH A SOURCE OR DRAIN REGION

(71) Applicant: Intel Corporation, Santa Clara, CA (US)

(72) Inventors: Robin Chao, Portland, OR (US); Chiao-Ti Huang, Portland, OR (US); Tao Chu, Portland, OR (US); Guowei Xu, Portland, OR (US); Feng Zhang, Hillsboro, OR (US); Ting-Hsiang Hung, Beaverton, OR (US); Kan Zhang, HILLSBORO, OR (US); Yang Zhang, Rio Rancho, NM (US); Chia-Ching Lin, Portland, OR (US); Anand S. Murthy, Portland, OR (US)

(73) Assignee: Intel Corporation, Santa Clara, CA (US)

(21) Appl. No.: 18/390,380

(22) Filed: Dec. 20, 2023

(51) Int. Cl. H01L 29/786; H01L 29/06; H01L 29/423; H01L 29/775

(52) U.S. Cl. CPC H10D 30/6757; H10D 30/43; H10D 30/6735; H10D 62/121

(57) ABSTRACT

A fabrication method and associated integrated circuit (IC) structures and devices that include a metal-all-around contact structure coupled with an S/D region are described herein. In one example, an IC structure may include a region of a doped semiconductor material. An IC structure may include a stack of nanoribbons of a semiconductor material including first portions and second portions on either side of the region, wherein the first portions are in contact with a first side of the region and the second portions are in contact with a second side of the region. An IC structure may include a conductive material over portions of the region between the first side and the second side in a same layer as at least one of the nanoribbons of the stack.

### BACKGROUND

For the past several decades, the scaling of features in integrated circuits (ICs) has been a driving force behind an ever-growing semiconductor industry. Scaling to smaller and smaller features enables increased densities of functional units on the limited real estate of semiconductor chips. For example, shrinking transistor size allows for the incorporation of an increased number of memory or logic devices on a chip, lending to the fabrication of products with increased capacity. The drive for the ever-increasing capacity, however, is not without issue. The necessity to optimize fabrication and performance of each component is becoming increasingly significant.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIG. 1 provides a perspective view of an example nanoribbon field-effect transistor (FET), according to one embodiment of the present disclosure.

FIG. 2 is a top-down view of an IC device that may include a metal-all-around contact structure coupled with a source or drain region, according to one embodiment of the present disclosure.

FIG. 3 is a flow diagram of an example method for fabricating an IC structure that includes a metal-all-around contact structure coupled with a source or drain region, in accordance with some embodiments.

FIGS. 4A-4B, 5A-5B, 6A-6B, 7A-7B, 8A-8B, 9A-9B, 10A-10B, 11A-11B, and 12A-12B provide cross-sectional side views at various stages in the fabrication of an example IC structure according to the method of FIG. 3, in accordance with some embodiments.

FIG. 13 is a flow diagram of an example method for fabricating an IC structure that includes a metal-all-around contact structure coupled with a source or drain region, in accordance with some embodiments.

FIGS. 14-20 provide cross-sectional side views at various stages in the fabrication of an example IC structure according to the method of FIG. 13, in accordance with some embodiments.

FIG. 21 is a top view of a wafer and dies that may include any of the IC devices disclosed herein, in accordance with any of the embodiments disclosed herein.

FIG. 22 is a side, cross-sectional view of an IC package that may include any of the IC devices disclosed herein, in accordance with various embodiments.

FIG. 23 is a side, cross-sectional view of an IC device assembly that may include any of the IC devices disclosed herein, in accordance with any of the embodiments disclosed herein.

FIG. 24 is a block diagram of an example electrical device that may include any of the IC devices disclosed herein, in accordance with any of the embodiments disclosed herein.

### DETAILED DESCRIPTION

Disclosed herein are metal-all-around contact structures for source or drain regions (referred to herein as “S/D regions”). The systems, methods and devices of this disclosure each have several innovative aspects, no single one of which is solely responsible for all desirable attributes disclosed herein. Details of one or more implementations of the subject matter described in this specification are set forth in the description below and the accompanying drawings.

As IC structures become more compact with smaller feature sizes and higher device density, new challenges arise in the fabrication processes of such devices. For example, as feature sizes shrink, the contact area between features may decrease, which can result in increased resistance. For example, limiting the contact area between an S/D region and an S/D contact to a top surface of the S/D region can result in high resistance, which can negatively impact device performance. Various attempts to increase the S/D contact area have resulted in higher capacitance and/or decreased channel compressive stress, which may also negatively impact device performance.

In one example, an S/D contact structure with a larger contact area can be achieved by forming a sacrificial liner around the S/D region (e.g., prior to forming a liner of an insulator material around the S/D region). When forming the S/D contact structure, the sacrificial liner can be removed (e.g., with an isotropic etch), and a conductive material can be provided around the S/D region in the space where the sacrificial liner was removed. In one example, a conformal layer of an interface material may be formed around the S/D region before providing the conductive material. In one such example, the technique can enable forming a metal-all-around contact structure for an S/D region from a front side and/or from a back side of the IC structure. According to some examples, a metal-all-around contact structure can enable lower resistance in the S/D contact without significantly increasing capacitance and/or without decreasing channel stress.

IC structures as described herein, in particular IC structures including a metal-all-around contact structure coupled with an S/D region, may be implemented in one or more components associated with an IC or/and between various such components. In various embodiments, components associated with an IC include, for example, transistors, diodes, power sources, resistors, capacitors, inductors, sensors, transceivers, receivers, antennas, etc. Components associated with an IC may include those that are mounted on an IC or those connected to an IC. The IC may be either analog or digital and may be used in a number of applications, such as microprocessors, optoelectronics, logic blocks, audio amplifiers, etc., depending on the components associated with the IC. In some embodiments, IC structures as described herein may be included in a radio frequency IC (RFIC), which may, e.g., be included in any component associated with an IC of a radio frequency (RF) receiver, an RF transmitter, or an RF transceiver, e.g., as used in telecommunications within base stations (BS) or user equipment (UE). Such components may include, but are not limited to, power amplifiers, low-noise amplifiers, RF filters (including arrays of RF filters, or RF filter banks), switches, upconverters, downconverters, and duplexers. In some embodiments, IC structures as described herein may be included in memory devices or circuits. In some embodiments, IC structures as described herein may be employed as part of a chipset for executing one or more related functions in a computer.

For purposes of explanation, specific numbers, materials and configurations are set forth in order to provide a thorough understanding of the illustrative implementations. However, it will be apparent to one skilled in the art that the present disclosure may be practiced without the specific details or/and that the present disclosure may be practiced with only some of the described aspects. In other instances, well-known features are omitted or simplified in order not to obscure the illustrative implementations. The terms “substantially,” “close,” “approximately,” “near,” and “about,” generally refer to being within +/−10% of a target value, e.g., within +/−5% of a target value, based on the context of a particular value as described herein or as known in the art. Similarly, terms indicating orientation of various elements, e.g., “coplanar,” “perpendicular,” “orthogonal,” “parallel,” or any other angle between the elements, generally refer to being within +/−10% of a target value, e.g., within +/−5% of a target value, based on the context of a particular value as described herein or as known in the art.

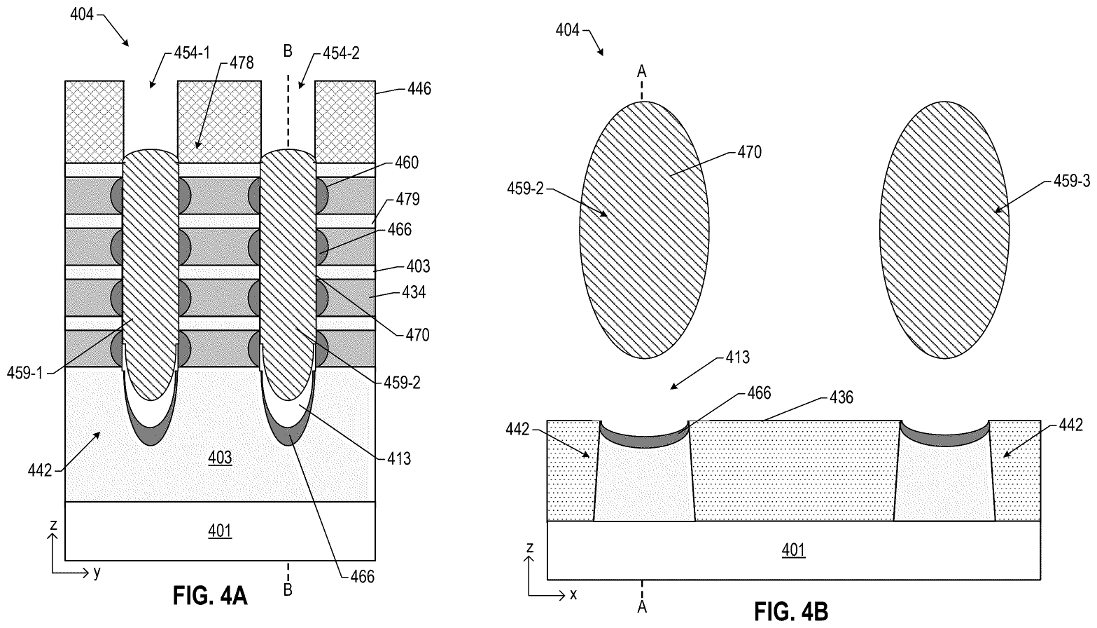

In the following description, references are made to the accompanying drawings that form a part hereof, and in which is shown, by way of illustration, embodiments that may be practiced. It is to be understood that other embodiments may be utilized, and structural or logical changes may be made without departing from the scope of the present disclosure. Therefore, the following detailed description is not to be taken in a limiting sense. For convenience, if a collection of drawings designated with different letters are present, e.g., FIGS. 4A-4B, such a collection may be referred to herein without the letters, e.g., as “FIG. 4.”

In the drawings, while some schematic illustrations of example structures of various devices and assemblies described herein may be shown with precise right angles and straight lines, this is simply for ease of illustration, and embodiments of these assemblies may be curved, rounded, or otherwise irregularly shaped as dictated by, and sometimes inevitable due to, the fabricating processes used to fabricate semiconductor device assemblies. Therefore, it is to be understood that such schematic illustrations may not reflect real-life process limitations which may cause the features to not look so “ideal” when any of the structures described herein are examined using e.g., scanning electron microscopy (SEM) images or transmission electron microscope (TEM) images. In such images of real structures, possible processing defects could also be visible, e.g., not-perfectly straight edges of materials, tapered vias or other openings, inadvertent rounding of corners or variations in thicknesses of different material layers, occasional screw, edge, or combination dislocations within the crystalline region, and/or occasional dislocation defects of single atoms or clusters of atoms. There may be other defects not listed here but that are common within the field of device fabrication. Inspection of layout and mask data and reverse engineering of parts of a device to reconstruct the circuit using e.g., optical microscopy, TEM, or SEM, and/or inspection of a cross-section of a device to detect the shape and the location of various device elements described herein using, e.g., Physical Failure Analysis (PFA) would allow determination of the presence of IC structures that include a metal-all-around contact structure coupled with an S/D region.

Various aspects of the illustrative implementations will be described using terms commonly employed by those skilled in the art to convey the substance of their work to others skilled in the art. For example, the terms “oxide,” “carbide,” “nitride,” “silicide,” etc. refer to compounds containing, respectively, oxygen, carbon, nitrogen, silicon, etc.; the term “high-k dielectric” refers to a material having a higher dielectric constant than silicon oxide; the term “low-k dielectric” refers to a material having a lower dielectric constant than silicon oxide. Materials referred to herein with formulas or as compounds cover all materials that include elements of the formula or a compound, e.g., TiSi or titanium silicide may refer to any material that includes titanium and silicon, WN or tungsten nitride may refer to any material that includes tungsten and nitrogen, etc. The term “insulating” means “electrically insulating,” the term “conducting” means “electrically conducting,” unless otherwise specified. Furthermore, the term “connected” may be used to describe a direct electrical or magnetic connection between the things that are connected, without any intermediary devices, while the term “coupled” may be used to describe either a direct electrical or magnetic connection between the things that are connected, or an indirect connection through one or more passive or active intermediary devices. A first component described to be electrically coupled to a second component means that the first component is in conductive contact with the second component (i.e., that a conductive pathway is provided to route electrical signals/power between the first and second components).

Various operations may be described as multiple discrete actions or operations in turn, in a manner that is most helpful in understanding the claimed subject matter. However, the order of description should not be construed as to imply that these operations are necessarily order dependent. These operations may not be performed in the order of presentation. Operations described may be performed in a different order from the described embodiment. Various additional operations may be performed, and/or described operations may be omitted in additional embodiments.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). The term “between,” when used with reference to measurement ranges, is inclusive of the ends of the measurement ranges.

The description uses the phrases “in an embodiment” or “in embodiments,” which may each refer to one or more of the same or different embodiments. The terms “comprising,” “including,” “having,” and the like, as used with respect to embodiments of the present disclosure, are synonymous. The disclosure may use perspective-based descriptions such as “above,” “below,” “top,” “bottom,” and “side”; such descriptions are used to facilitate the discussion and are not intended to restrict the application of disclosed embodiments. The accompanying drawings are not necessarily drawn to scale. Unless otherwise specified, the use of the ordinal adjectives “first,” “second,” and “third,” etc., to describe a common object, merely indicate that different instances of like objects are being referred to and are not intended to imply that the objects so described must be in a given sequence, either temporally, spatially, in ranking or in any other manner. Although some materials may be described in singular form, such materials may include a plurality of materials, e.g., a semiconductor material may include two or more different semiconductor materials.

IC structures including a metal-all-around contact structure coupled with an S/D region may also include non-planar transistors such as double-gate transistors, tri-gate transistors, FinFETs, and nanowire/nanoribbon/nanosheet transistors refer to transistors having a non-planar architecture. In comparison to a planar architecture where the transistor channel has only one confinement surface, a non-planar architecture is any type of architecture where the transistor channel has more than one confinement surface. A confinement surface refers to a particular orientation of the channel surface that is confined by the gate field. Non-planar transistors potentially improve performance relative to transistors having a planar architecture, such as single-gate transistors.

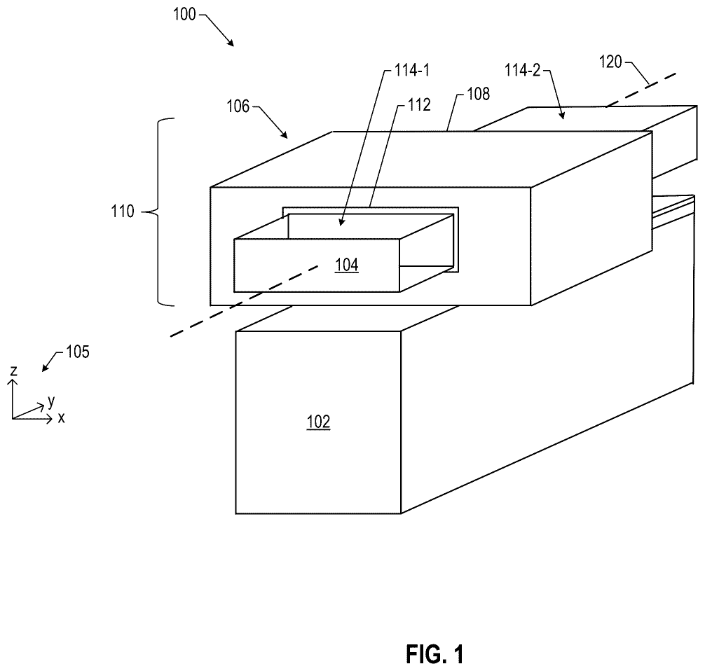

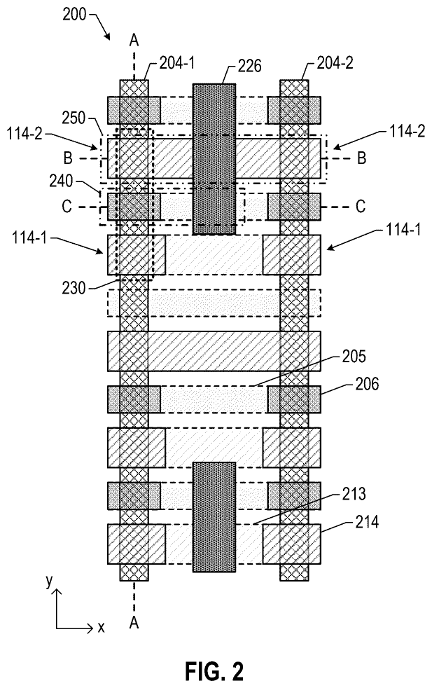

Nanoribbon transistors may be particularly advantageous for continued scaling of complementary metal-oxide-semiconductor (CMOS) technology nodes due to the potential to form gates on all four sides of a channel material (hence, such transistors are sometimes referred to as “gate all around” transistors). Therefore, some IC structures illustrated herein show nanoribbon transistors as an example (e.g., IC structures shown in FIG. 1, FIG. 2, FIGS. 4-12, and 14-20), although IC structures that include a metal-all-around contact structure coupled with an S/D region as described herein may include other devices instead of or in addition to nanoribbon transistors, and are not limited to such transistors.

As used herein, the term “nanoribbon” refers to an elongated structure of a semiconductor material having a longitudinal axis parallel to a support structure (e.g., a substrate, a die, a chip, or a wafer) over which such a structure is built. Typically, a length of a such a structure (i.e., a dimension measured along the longitudinal axis, shown in the present drawings to be along the y-axis of an example x-y-z coordinate system 105 shown in FIG. 1) is greater than each of a width (i.e., a dimension measured along the x-axis of the coordinate system 105) and a thickness/height (i.e., a dimension measured along the z-axis of the coordinate system 105). In some settings, the terms “nanoribbon” or “nanosheet” have been used to describe elongated semiconductor structures that have a rectangular transverse cross-section (i.e., a cross-section in a plane perpendicular to the longitudinal axis of the structure), while the term “nanowire” has been used to describe similar elongated structures but with circular transverse cross-sections. In the present disclosure, the term “nanoribbon” is used to refer to all such nanowires, nanoribbons, and nanosheets, as well as elongated semiconductor structures with a longitudinal axis parallel to the support structures and with having transverse cross-sections of any geometry (e.g., transverse cross-sections in the shape of an oval or a polygon with rounded corners). A transistor may then be described as a “nanoribbon transistor” if the channel of the transistor is a portion of a nanoribbon, i.e., a portion around which a gate stack of a transistor may wrap around. The semiconductor material in the portion of the nanoribbon that forms a channel of a transistor may be referred to as a “channel material,” with source and drain regions of a transistor provided on either side of the channel material.

FIG. 1 provides a perspective view of an example IC structure 100 with a nanoribbon transistor 110, according to some embodiments of the present disclosure. As shown in FIG. 1, the IC structure 100 includes a semiconductor material formed as a nanoribbon 104 extending substantially parallel to a support 102. The transistor 110 may be formed on the basis of the nanoribbon 104 by having a gate stack 106 wrap around at least a portion of the nanoribbon referred to as a “channel portion” and by having source and drain regions, shown in FIG. 1 as a first S/D region 114-1 and a second S/D region 114-2, on either side of the gate stack 106. One of the S/D regions 114-1 and 114-2 is a source region and the other one is a drain region. However, because, as is common in the field of FETs, designations of source and drain are often interchangeable, they are simply referred to herein as a first S/D region 114-1 and a second S/D region 114-2.

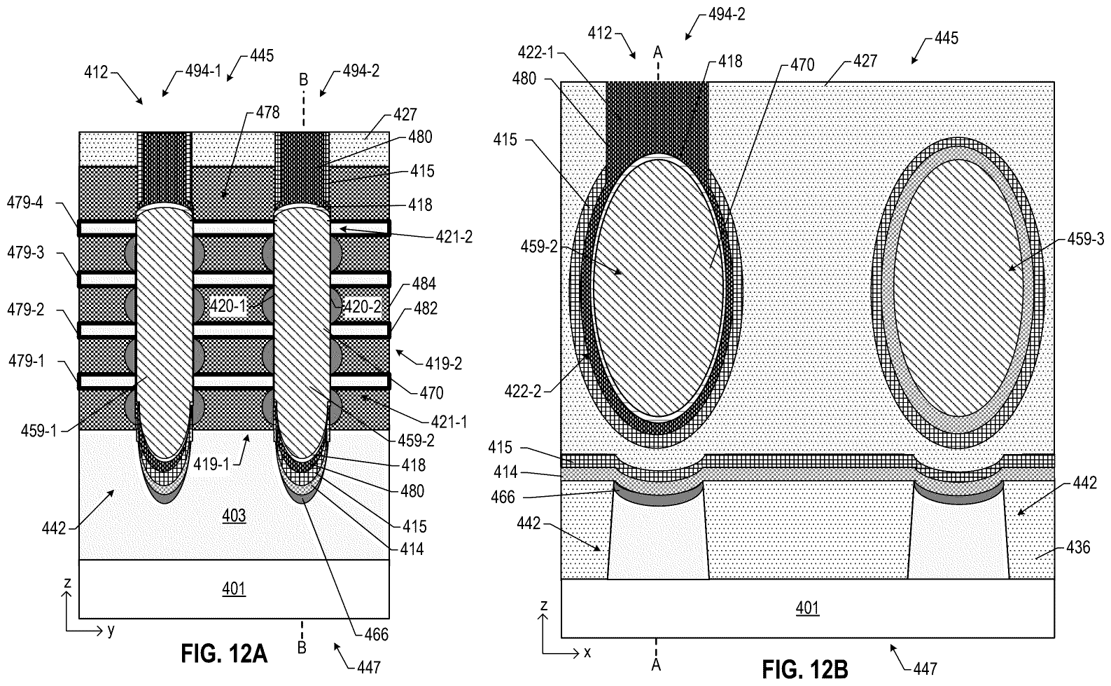

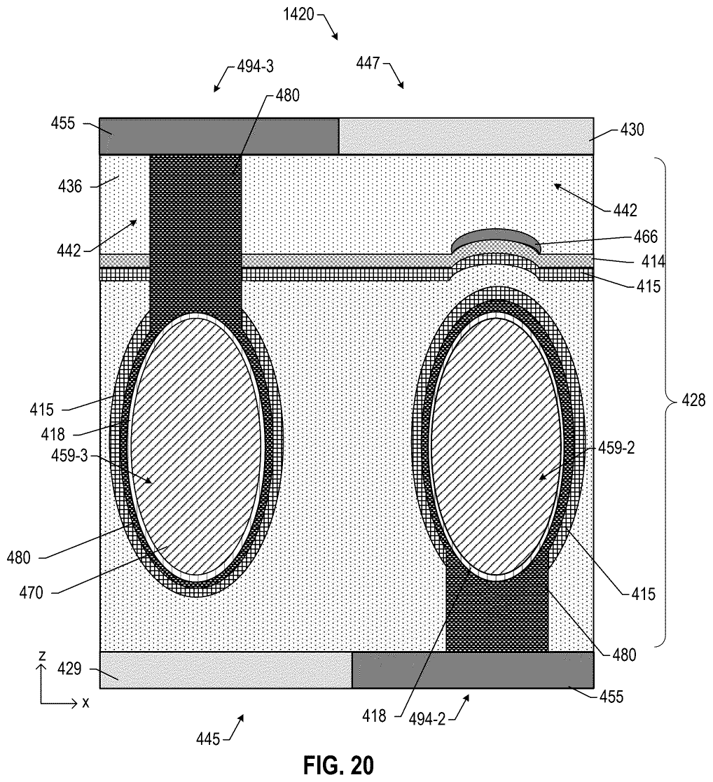

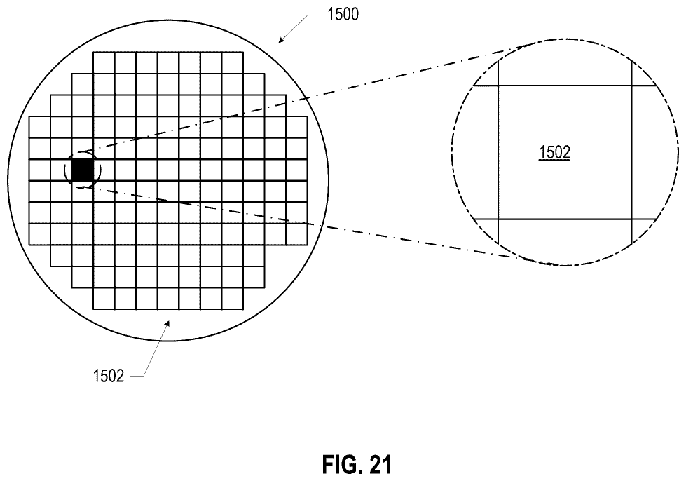

Implementations of the present disclosure may be formed or carried out on any suitable support 102, such as a substrate, a die, a wafer, or a chip. The support 102 may, e.g., be the wafer 1500 of FIG. 21, discussed below, and may be, or be included in, a die, e.g., the singulated die 1502 of FIG. 21, discussed below. The support 102 may be a semiconductor substrate composed of semiconductor material systems including, for example, N-type or P-type materials systems. In one implementation, the semiconductor substrate may be a crystalline substrate formed using a bulk silicon or a silicon-on-insulator (SOI) substructure. In other implementations, the semiconductor substrate may be formed using alternate materials, which may or may not be combined with silicon, that include, but are not limited to, germanium, silicon germanium, indium antimonide, lead telluride, indium arsenide, indium phosphide, gallium arsenide, aluminum gallium arsenide, aluminum arsenide, indium aluminum arsenide, aluminum indium antimonide, indium gallium arsenide, gallium nitride, indium gallium nitride, aluminum indium nitride or gallium antimonide, or other combinations of group III-V materials (i.e., materials from groups III and V of the periodic system of elements), group II-VI (i.e., materials from groups II and IV of the periodic system of elements), or group IV materials (i.e., materials from group IV of the periodic system of elements). In some embodiments, the substrate may be non-crystalline. In some embodiments, the support 102 may be a printed circuit board (PCB) substrate, a package substrate, an interposer, a wafer, or a die. Although a few examples of materials from which the support 102 may be formed are described here, any material that may serve as a foundation upon which an IC structure including a metal-all-around contact structure coupled with an S/D region as described herein may be built falls within the spirit and scope of the present disclosure. Although only one nanoribbon 104 is shown in FIG. 1, the IC structure 100 may include a stack of such nanoribbons where a plurality of nanoribbons 104 are stacked above one another. For example, FIGS. 12 and 20 shows an IC structure that may be an example of the IC structure 100. In some embodiments, a portion of the support 102 right below the lowest nanoribbon 104 of the stack may be shaped as a subfin extending away from a base, as is known in the field of nanoribbon transistors.

The nanoribbon 104 may take the form of a nanowire or nanoribbon, for example. In some embodiments, an area of a transversal cross-section of the nanoribbon 104 (i.e., an area in the x-z plane of an x-y-z coordinate system 105 shown in FIG. 1, perpendicular to a longitudinal axis 120 of the nanoribbon 104) may be between about 25 and 10000 square nanometers, including all values and ranges therein (e.g., between about 25 and 1000 square nanometers, or between about 25 and 500 square nanometers). In some embodiments, a width of the nanoribbon 104 (i.e., a dimension measured in a plane parallel to the support 102 and in a direction perpendicular to the longitudinal axis 120 of the nanoribbon 104, e.g., along the x-axis of the coordinate system 105) may be at least about 3 times larger than a height of the nanoribbon 104 (i.e., a dimension measured in a plane perpendicular to the support 102, e.g., along the z-axis of the coordinate system 105), including all values and ranges therein, e.g., at least about 4 times larger, or at least about 5 times larger. Although the nanoribbon 104 illustrated in FIG. 1 is shown as having a rectangular cross-section, the nanoribbon 104 may instead have a cross-section that is rounded at corners or otherwise irregularly shaped, and the gate stack 106 may conform to the shape of the nanoribbon 104. The term “face” of a nanoribbon may refer to the side of the nanoribbon 104 that is larger than the side perpendicular to it (when measured in a plane substantially perpendicular to the longitudinal axis 120 of the nanoribbon 104), the latter side being referred to as a “sidewall” of a nanoribbon.

In various embodiments, the semiconductor material of the nanoribbon 104 may be composed of semiconductor material systems including, for example, N-type or P-type materials systems. In some embodiments, the nanoribbon 104 may include a high mobility oxide semiconductor material, such as tin oxide, antimony oxide, indium oxide, indium tin oxide, titanium oxide, zinc oxide, indium zinc oxide, gallium oxide, titanium oxynitride, ruthenium oxide, or tungsten oxide. In some embodiments, the nanoribbon 104 may include a combination of semiconductor materials. In some embodiments, the nanoribbon 104 may include a monocrystalline semiconductor, such as silicon (Si) or germanium (Ge). In some embodiments, the nanoribbon 104 may include a compound semiconductor with a first sub-lattice of at least one element from group Ill of the periodic table (e.g., Al, Ga, In), and a second sub-lattice of at least one element of group V of the periodic table (e.g., P, As, Sb).

For some example N-type transistor embodiments (i.e., for the embodiments where the transistor 110 is an N-type metal-oxide-semiconductor (NMOS) transistor), the channel material of the nanoribbon 104 may include a III-V material having a relatively high electron mobility, such as, but not limited to InGaAs, InP, InSb, and InAs. For some such embodiments, the channel material of the nanoribbon 104 may be a ternary III-V alloy, such as InGaAs, GaAsSb, InAsP, or InPSb. For some InₓGa₁₋ₓAs fin embodiments, In content (x) may be between 0.6 and 0.9, and may advantageously be at least 0.7 (e.g., In_{0.7}Ga_{0.3}As). For some example P-type transistor embodiments (i.e., for the embodiments where the transistor 110 is a P-type metal-oxide-semiconductor (PMOS) transistor), the channel material of the nanoribbon 104 may advantageously be a group IV material having a high hole mobility, such as, but not limited to Ge or a Ge-rich SiGe alloy. For some example embodiments, the channel material of the nanoribbon 104 may have a Ge content between 0.6 and 0.9, and advantageously may be at least 0.7.

In some embodiments, the channel material of the nanoribbon 104 may be a thin-film material, such as a high mobility oxide semiconductor material, such as tin oxide, antimony oxide, indium oxide, indium tin oxide, titanium oxide, zinc oxide, indium zinc oxide, indium gallium zinc oxide (IGZO), gallium oxide, titanium oxynitride, ruthenium oxide, or tungsten oxide. In general, if the transistor formed in the nanoribbon is a thin-film transistor (TFT), the channel material of the nanoribbon 104 may include one or more of tin oxide, cobalt oxide, copper oxide, antimony oxide, ruthenium oxide, tungsten oxide, zinc oxide, gallium oxide, titanium oxide, indium oxide, titanium oxynitride, indium tin oxide, indium zinc oxide, nickel oxide, niobium oxide, copper peroxide, IGZO, indium telluride, molybdenite, molybdenum diselenide, tungsten diselenide, tungsten disulfide, N- or P-type amorphous or polycrystalline silicon, germanium, indium gallium arsenide, silicon germanium, gallium nitride, aluminum gallium nitride, indium phosphite, and black phosphorus, each of which may possibly be doped with one or more of gallium, indium, aluminum, fluorine, boron, phosphorus, arsenic, nitrogen, tantalum, tungsten, and magnesium, etc. In some embodiments, the channel material of the nanoribbon 104 may have a thickness between about 5 and 75 nanometers, including all values and ranges therein. In some embodiments, a thin-film channel material may be deposited at relatively low temperatures, which allows depositing the channel material within the thermal budgets imposed on back-end fabrication to avoid damaging other components, e.g., front-end components such as the logic devices.

A gate stack 106 including a gate electrode material 108 and, optionally, a gate insulator material 112, may wrap entirely or almost entirely around a portion of the nanoribbon 104 as shown in FIG. 1, with the active region (channel region) of the channel material of the transistor 110 corresponding to the portion of the nanoribbon 104 wrapped by the gate stack 106. As shown in FIG. 1, the gate insulator material 112 may wrap around a transversal portion of the nanoribbon 104 and the gate electrode material 108 may wrap around the gate insulator material 112.

The gate electrode material 108 may include one or more gate electrode materials, where the choice of the gate electrode materials may depend on whether the transistor 110 is a PMOS transistor or an NMOS transistor. For a PMOS transistor, gate electrode materials that may be used in different portions of the gate electrode material 108 may include, but are not limited to, ruthenium, palladium, platinum, cobalt, nickel, and conductive metal oxides (e.g., ruthenium oxide). For an NMOS transistor, gate electrode materials that may be used in different portions of the gate electrode material 108 include, but are not limited to, hafnium, zirconium, titanium, tantalum, aluminum, alloys of these metals, and carbides of these metals (e.g., hafnium carbide, zirconium carbide, titanium carbide, tantalum carbide, and aluminum carbide). In some embodiments, the gate electrode material 108 may include a stack of a plurality of gate electrode materials, where zero or more materials of the stack are workfunction (WF) materials and at least one material of the stack is a fill metal layer. Further materials/layers may be included next to the gate electrode material 108 for other purposes, such as to act as a diffusion barrier layer or/and an adhesion layer.

In some embodiments, the gate insulator material 112 may include one or more high-k dielectrics including any of the materials discussed herein with reference to the insulator material that may surround portions of the transistor 110. In some embodiments, an annealing process may be carried out on the gate insulator material 112 during fabrication of the transistor 110 to improve the quality of the gate insulator material 112. The gate insulator material 112 may have a thickness that may, in some embodiments, be between about 0.5 nanometers and 3 nanometers, including all values and ranges therein (e.g., between about 1 and 3 nanometers, or between about 1 and 2 nanometers). In some embodiments, the gate stack 106 may be surrounded by a gate spacer, not shown in FIG. 1. Such a gate spacer would be configured to provide separation between the gate stack 106 and S/D contacts of the transistor 110 and could be made of a low-k dielectric material, some examples of which have been provided above.

Turning to the S/D regions 114-1, 114-2 of the transistor 110, in some embodiments, the S/D regions may be highly doped, e.g., with dopant concentrations of about 10²¹ cm⁻³, in order to advantageously form Ohmic contacts with the respective S/D contacts (not shown in FIG. 1), although these regions may also have lower dopant concentrations and may form Schottky contacts in some implementations. Irrespective of the exact doping levels, the S/D regions of a transistor are the regions having dopant concentration higher than in other regions, e.g., higher than a dopant concentration in the transistor channel (i.e., in a channel material extending between the first S/D region 114-1 and the second S/D region 114-2), and, therefore, may be referred to as “highly doped” (HD) regions. Even when doped to realize threshold voltage tuning as described herein, the channel portions of transistors typically include semiconductor materials with doping concentrations significantly smaller than those of the S/D regions 114-1, 114-2.

The S/D regions 114-1, 114-2 of the transistor 110 may generally be formed using either an implantation/diffusion process or an etching/deposition process. In the former process, dopants such as boron, aluminum, antimony, phosphorous, or arsenic may be ion-implanted into the nanoribbon 104 to form the source and drain regions. An annealing process that activates the dopants and causes them to diffuse further into the nanoribbon 104 may follow the ion implantation process. In the latter process, portions of the nanoribbon 104 may first be etched to form recesses at the locations of the future S/D regions 114-1, 114-2. An epitaxial deposition process may then be carried out to fill the recesses with material that is used to fabricate the S/D regions 114-1, 114-2. In some implementations, the S/D regions 114-1, 114-2 may be fabricated using a silicon alloy such as silicon germanium or silicon carbide. In some implementations, the epitaxially deposited silicon alloy may be doped in situ with dopants such as boron, arsenic, or phosphorous. In further embodiments, the S/D regions 114-1, 114-2 may be formed using one or more alternate semiconductor materials such as germanium or a group III-V material or alloy. And in further embodiments, one or more layers of metal and/or metal alloys may be used to form the S/D regions 114-1, 114-2. In some embodiments, a distance between the first and second S/D regions 114-1, 114-2 (i.e., a dimension measured along the longitudinal axis 120 of the nanoribbon 104) may be between about 5 and 40 nanometers, including all values and ranges therein (e.g., between about 22 and 35 nanometers, or between about 20 and 30 nanometers).

The IC structure 100 shown in FIG. 1, as well as IC structures shown in other drawings of the present disclosure, is intended to show relative arrangements of some of the components therein, and the IC structure 100, or portions thereof, may include other components that are not illustrated (e.g., electrical contacts to the S/D regions 114-1, 114-2 of the transistor 110, additional layers such as a spacer layer around the gate electrode of the transistor 110, etc.). For example, although not specifically illustrated in FIG. 1, a dielectric spacer may be provided between a first S/D contact (which may also be referred to as a “first S/D electrode”) coupled to a first S/D region 114-1 of the transistor 110 and the gate stack 106 as well as between a second S/D contact (which may also be referred to as a “second S/D electrode”) coupled to a second S/D region 114-2 of the transistor 110 and the gate stack 106 in order to provide electrical isolation between the source, gate, and drain electrodes. In another example, although not specifically illustrated in FIG. 1, at least portions of the transistor 110 may be surrounded in an insulator material, such as any suitable interlayer dielectric (ILD) material. In some embodiments, such an insulator material may be a high-k dielectric including elements such as hafnium, silicon, oxygen, titanium, tantalum, lanthanum, aluminum, zirconium, barium, strontium, yttrium, lead, scandium, niobium, and zinc. Examples of high-k materials that may be used for this purpose may include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, tantalum oxide, tantalum silicon oxide, lead scandium tantalum oxide, and lead zinc niobate. In other embodiments, the insulator material surrounding portions of the transistor 110 may be a low-k dielectric material. Some examples of low-k dielectric materials include, but are not limited to, silicon dioxide, carbon-doped oxide, silicon nitride, organic polymers such as perfluorocyclobutane or polytetrafluoroethylene, fused silica glass (FSG), and organosilicates such as silsesquioxane, siloxane, or organosilicate glass.

FIG. 2 is a top-down view of an IC structure 200 that may include a metal-all-around contact structure coupled with an S/D region, according to one embodiment of the present disclosure. Some of the materials are not shown in the top-down view in order to not obscure the drawing.

As shown in FIG. 2, the IC structure 200 may include two nanoribbon stacks 204-1 and 204-2, if the transistors to be implemented in the IC structure 200 are nanoribbon transistors such as the one illustrated in FIG. 1. Alternatively, what is now shown as nanoribbon stacks 204-1 and 204-2 could be fins, if the transistors to be implemented in the IC structure 200 are FinFETs. The nanoribbon stacks 204-1, 204-2 may include stacks of one or more nanoribbons 104 as described above and may be provided over a support such as the support 102 (not specifically shown in FIG. 2). The nanoribbon stacks 204-1, 204-2 may extend substantially parallel to one another, e.g., along the y-axis of the coordinate system 105, consistent with the illustration of FIG. 1. Metal gate lines 205 (shown in FIG. 2 to be within dashed contours) and S/D contact lines 213 may extend substantially perpendicular to the nanoribbon stacks 204-1, 204-2 and substantially parallel to one another, e.g., along the x-axis of the coordinate system 105. FIG. 2 illustrates that the metal gate lines 205 and the S/D contact lines 213 may be provided in an alternating manner. Metal gate lines 205 may be cut and removed where the deep trench vias are placed, so that gate contacts 206 effectively act as portions of the metal lines 205. In FIG. 2, portions of the metal gate lines 205 are shown with dashed contours, indicating that these are the portions where the metal gate lines 205 have been removed. The gate contacts 206 are in conductive contact with the gate stacks 106 (which are underneath the gate contacts 206 and, therefore, not seen in the view of FIG. 2) provided over channel portions of the nanoribbon stacks 204-1, 204-2, providing electrical connectivity to the gates of the nanoribbon transistors. Thus, portions of the gate contacts 206 intersecting the gate stacks 106 are in conductive contact with the gate stacks 106 and serve as gate contacts for the transistors.

Similarly, S/D contact lines 213 may be cut and removed where the deep trench vias are placed, so that S/D contacts 214 effectively act as portions of the S/D contact lines 213. In FIG. 2, portions of the S/D contact lines 213 are shown with dashed contours, indicating that these are the portion where the S/D contact lines 213 have been removed. The S/D contacts 214 are provided over S/D regions 114-1, 114-2 (which are underneath the S/D contacts 214 and, therefore, not seen in the view of FIG. 2) of the nanoribbon stacks 204-1, 204-2, providing electrical connectivity to the S/D regions 114-1, 114-2 of the nanoribbon transistors. Thus, portions of the S/D contacts 214 intersecting the S/D regions 114-1, 114-2 are in conductive contact with the S/D regions 114-1, 114-2 and serve as S/D contacts for the transistors.

FIG. 2 further illustrates that deep trench vias 226 may be provided in the vicinity of the transistors formed on the basis of the nanoribbon stacks 204-1, 204-2. Two instances of the deep trench vias 226 are shown in FIG. 2, but, in other embodiments, any other number of one or more deep trench vias 226 may be included in the IC structure 200. Similarly, while a particular arrangement of gate stacks 106, metal gate lines 205, gate contacts 206, S/D contact lines 213, and S/D contacts 214 is shown in FIG. 1 and FIG. 2, in other embodiments, these elements may be arranged differently within the IC structure 200. In order to further illustrate details of the IC structure 200, FIG. 2 shows a portion 230 (illustrated with a dotted contour), a portion 240 (illustrated with a dot-dashed contour), and a portion 250 (illustrated with a double-dot-dashed contour). The portion 230 indicates an approximate outline of an example transistor such as the transistor 110, provided over the nanoribbon stack 204-1. The portion 240 illustrates a portion of the IC structure 200 with a gate contact provided over a gate stack 106 over a channel portion of the nanoribbon stack 204-1 and a deep trench via 226. FIGS. 4A-4B, which are discussed below, are cross-sectional side views along different cross-sections of an example IC structure, such as cross-sectional views of the portions 230 and 250 of FIG. 2.

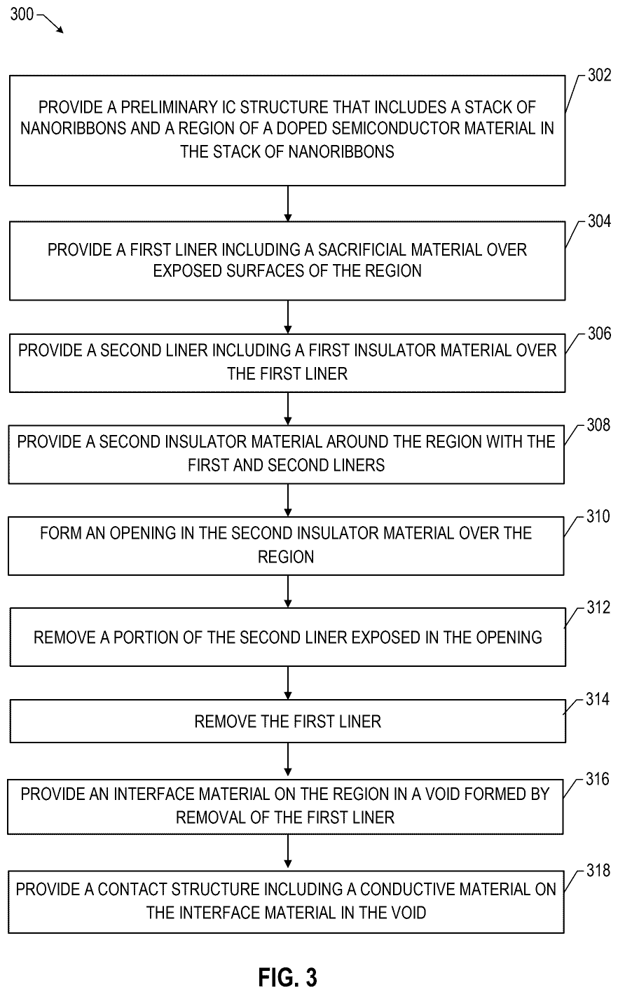

FIG. 3 is a flow diagram of an example method for fabricating an IC structure that includes a metal-all-around contact structure coupled with an S/D region, in accordance with some embodiments. Although the operations of the method of FIG. 3 are illustrated once each and in a particular order, the operations may be performed in any suitable order and repeated as desired. For example, one or more operations may be performed in parallel to fabricate multiple IC structures with a metal-all-around contact structure coupled with an S/D region substantially simultaneously. In another example, the operations may be performed in a different order to reflect the structure of an IC device in which a metal-all-around contact structure coupled with an S/D region will be implemented.

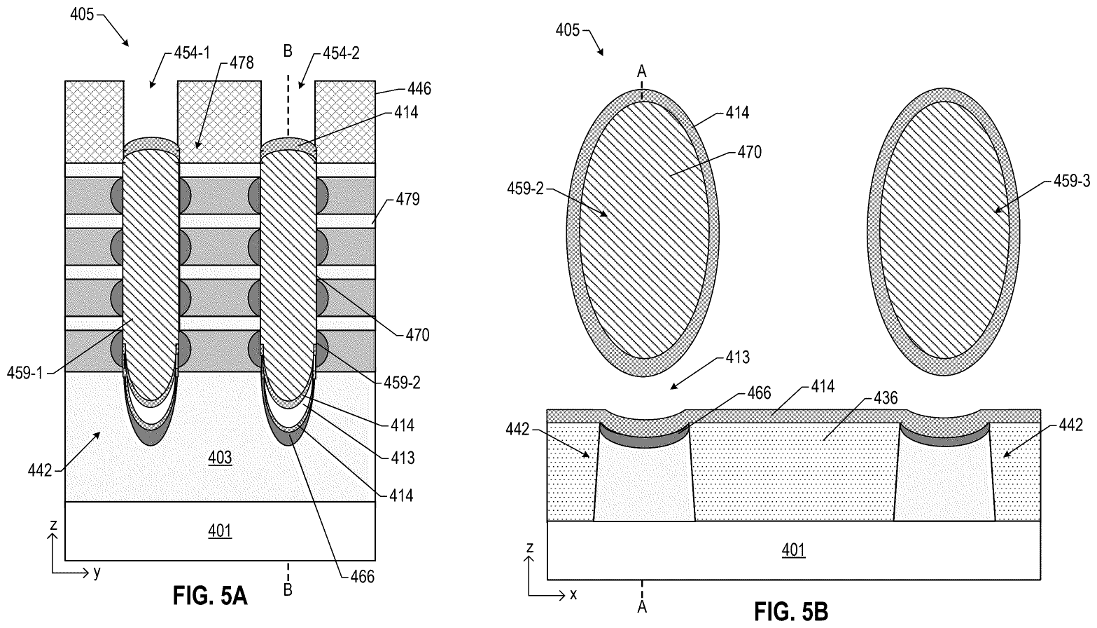

In addition, the example fabricating method of FIG. 3 may include other operations not specifically shown in FIG. 3, such as various cleaning or planarization operations as known in the art. For example, in some embodiments, a support, as well as layers of various other materials subsequently deposited thereon, may be cleaned prior to, after, or during any of the processes of the methods described herein, e.g., to remove oxides, surface-bound organic and metallic contaminants, as well as subsurface contamination. In some embodiments, cleaning may be carried out using e.g., a chemical solutions (such as peroxide), and/or with ultraviolet (UV) radiation combined with ozone, and/or oxidizing the surface (e.g., using thermal oxidation) then removing the oxide (e.g., using hydrofluoric acid (HF)). In another example, the intermediate IC structures described herein may be planarized prior to, after, or during any of the processes of the method of FIG. 5 described herein, e.g., to remove overburden or excess materials. In some embodiments, planarization may be carried out using either wet or dry planarization processes, e.g., planarization be a chemical mechanical planarization (CMP), which may be understood as a process that utilizes a polishing surface, an abrasive and a slurry to remove the overburden and planarize the surface.

FIGS. 4A-4B, 5A-5B, 6A-6B, 7A-7B, 8A-8B, 9A-9B, 10A-10B, 11A-11B, and 12A-12B provide cross-sectional side views at various stages in the fabrication of an example IC structure according to the method of FIG. 3, in accordance with some embodiments. FIGS. 4-12 each include two figures, labeled with letters A and B (e.g., FIG. 4 includes FIGS. 4A and 4B), providing different cross-sectional side views of a given IC structure. In particular, those figures of FIGS. 4-12 that are labeled with a letter A (e.g., FIG. 4A) illustrate cross-sections in the y-z plane of the example coordinate system shown in FIG. 1 along a plane AA shown in a corresponding figure labeled with a letter B (e.g., along a plane AA shown in FIG. 4B). Those figures of FIGS. 4-12 that are labeled with a letter B (e.g., FIG. 4B) illustrate cross-sections in the x-z plane of the example coordinate system shown in FIG. 1 along a plane BB shown in FIG. 4A. In order to not clutter the drawings, planes AA and BB may not be shown in some of FIGS. 4-12.

Turning to FIG. 3, the method 300 begins with a process 302 of providing a preliminary IC structure including a stack of nanoribbons and a region of a doped semiconductor material in the stack of nanoribbons. An IC structure 404 of FIGS. 4A-4B illustrates an example result of the process 302. As mentioned above, FIGS. 4A-4B illustrate cross-sectional side views along different cross-sections of the IC structure 404. In particular, FIG. 4A illustrates a cross-sectional side view of a portion of the IC structure 404 similar to the portion 230 along a plane AA shown in FIG. 2. FIG. 4B illustrates a cross-sectional side view of a portion of the IC structure similar to the portion 250 along a plane BB shown in FIG. 2 (except a conductive via is not shown in FIG. 4B).

As shown in FIG. 4A, the IC structure 404 includes a stack 478 of nanoribbons 479 over a support 401. In one example, the IC structure 404 includes a transistor similar to the transistor 110 but built on the basis of a stack 478 of a plurality of nanoribbons 479 instead of just one nanoribbon as shown in FIG. 1. While four nanoribbons 479 are shown to be included in the nanoribbon stack 478, in other embodiments, fewer nanoribbons or more nanoribbons may be included. FIG. 4A illustrates a semiconductor material 403 as the material of the nanoribbons 479, further illustrating a subfin 442 of the semiconductor material 403 below the nanoribbon stack 478, although in some embodiments the nanoribbons 479 and at least a portion of the subfin 442 may include semiconductor materials of different material compositions. FIG. 4A illustrates a material 446 over the stack 478 of nanoribbons, which may be a dummy gate or replacement gate provided around the fin. In one example, the material 446 may be any suitable material such as polysilicon.

The nanoribbon stack 478 may be formed by providing a stack of alternate layers of the semiconductor material 403 and another material 434 (e.g., another semiconductor material) and forming a fin from the stack. The semiconductor material 403 may be any of the semiconductor/channel materials described above with reference to the nanoribbon 104 of FIG. 1. The material 434 may be any suitable material that is etch-selective with respect to the semiconductor material 403 so that, in a later process, the material 434 may be etched away to form the nanoribbons 479 of the semiconductor material 403. As known in the art, two materials are said to be “etch-selective” (or said to have “sufficient etch selectivity”) with respect to one another when etchants used to etch one material do not substantially etch the other, enabling selective etching of one material but not the other. For example, in some embodiments, the semiconductor material 403 may be silicon while the material 434 may be a second semiconductor material such as silicon germanium. In another example, the semiconductor material 403 may be silicon germanium, while the material 434 may be silicon. In other examples, the material 434 may be made of a non-semiconductor material, e.g., of an insulator material, as long as this material is sufficiently etch-selective with respect to the semiconductor material 403.

Thus, the material 434 may be any suitable sacrificial material that is etch-selective with respect to the semiconductor material 403. Selecting the material 434 to be a semiconductor material may be particularly advantageous because it may improve quality of the semiconductor material 403 if the semiconductor material 403 is epitaxially grown on the material 434. In some embodiments, the process may include epitaxially growing layers of the semiconductor material 403 and the material 434 (e.g., another semiconductor material) in an alternating manner. In other embodiments, alternate layers of the semiconductor material 403 and the material 434 may be provided in the process using other techniques, such as layer transfer or thin-film deposition. Although FIG. 4A illustrates the same semiconductor material 403 in various layers of the IC structure 404, in general, material compositions of a semiconductor material from which nanoribbons will later be formed in different layers of the IC structure 404 may be different. For example, the semiconductor material 403 of one layer of the IC structure 404 may be silicon while the semiconductor material 403 of another layer of the IC structure 404 may be a III-N semiconductor material such as GaN.

FIG. 4A further illustrates a first S/D region 459-1 and a second S/D region 459-2 extending through the nanoribbon stack 478. FIG. 4B illustrates a third S/D region 459-3. The S/D regions 459-1, 459-2, and 459-3 may be referred to herein as “S/D regions 459.” Referring to FIG. 4A, in one example, the S/D regions 459-1, 459-2 include a semiconductor material 470 (e.g., a doped semiconductor material) in S/D openings 454-1, 454-2 formed in the stack 478. Although the S/D regions 459 are depicted as including the same semiconductor material 470, the S/D regions 459 may include the same or a different semiconductor material. In the example illustrated in FIG. 4A, prior to providing the semiconductor material 470 in the openings 454-1, 454-2, the material 434 was recessed away from the original side walls of the S/D openings 454-1, 454-2 to form “dimples” 460 on sidewalls of the openings 454-1, 454-2. In the example illustrated in FIG. 4A, the IC structure 404 includes a spacer or insulator material 466 in the dimples 460, which can separate the S/D regions 459-1, 459-2 from the gate electrode material that is provided in a later process. The insulator material 466 may also line bottoms of the openings 454 (e.g., in the subfin 442), as shown in FIG. 4A. The insulator material 466 may include any of the insulator materials described herein, e.g., any of the ILD materials described above.

In one example, the semiconductor material 470 is epitaxially grown in the openings 454-1, 454-2 (e.g., on the exposed surfaces of the semiconductor material 403 of the nanoribbons 479 on sidewalls of the openings 454). In some examples, the semiconductor material 470 of the S/D regions 459 does not completely fill the openings 454 (which may be intentional or unintentional), resulting in a void or gap 413 at bottoms of the S/D regions 459. In the example illustrated in FIG. 4A, the S/D regions 459 include a gap 413 between the insulator material 466 and the semiconductor material 470 of the S/D regions 459 (e.g., at bottoms of the openings 454).

FIG. 4B provides another illustration of the IC structure 404 along the plane BB shown in FIG. 4A (i.e., a cut across S/D region 459-2 of the nanoribbon stack 478 and across another S/D region 459-3 in another nanoribbon stack). FIG. 4B shows the plane AA along which the cut of FIG. 4A is shown. The S/D regions 459-2, 459-3 are shown above respective subfins 442. The subfins may be at least partially surrounded by an insulator material 436. In the example shown in FIG. 4B, a layer of the insulator material 466 provided in the openings 454 may also line the subfins. As mentioned above, the semiconductor material 470 of the S/D regions 459-2, 459-3 may be epitaxially grown on the semiconductor material 403 of the nanoribbons 479 from sidewalls of the openings 454. In one such example, the semiconductor material 470 initially grows separate epitaxial structures on the exposed semiconductor material 403 on sidewalls of the openings 454, and the separate epitaxial structures eventually merge together to form an epitaxial structure of the semiconductor material 470 as shown in FIG. 4. In some examples, the semiconductor material 470 grows to at least partially fill the openings 454 vertically and also grows laterally out from the nanoribbons 479 (e.g., along the x-axis away from both sides of the nanoribbons 479). Thus, the semiconductor material 470 of the S/D regions 459 appear to be suspended in space in the view shown in FIG. 4B, but the semiconductor material 470 of the S/D regions 459 are structurally supported by the nanoribbons 479 on either side of the S/D regions 459. Thus, the S/D regions 459 include portions that extend or protrude beyond the nanoribbon stack 478, as shown in FIG. 4B.

Turning again to FIG. 3, the method 300 continues with a process 304 of providing a first liner including a sacrificial material (e.g., a sacrificial liner) over exposed surfaces of the region. An IC structure 405 of FIGS. 5A-5B illustrates an example result of the process 304. As can be seen in FIG. 5, a sacrificial material 414 lines the semiconductor material 470 of the S/D regions 459. In the example illustrated in FIG. 5, the sacrificial material 414 forms a conformal liner that wraps around the S/D regions. In some examples, the sacrificial material 414 is provided all around the S/D regions 459, e.g., over top portions of the S/D regions 459 in the openings 454 and under bottom portions of the S/D regions 459 (e.g., around the bottom of the epitaxial structures in the gap 413). The sacrificial material 414 may also be deposited over exposed surfaces under the S/D regions 459 and between nanoribbon stacks, as shown in FIG. 5B, which depicts the sacrificial material 414 over the insulator material 436 and on the insulator material 466 lining the subfins 442.

The sacrificial material 414 may be any suitable sacrificial material that may be later removed without excessively damaging surrounding materials. For example, the sacrificial material 414 may be an insulator material that is etch-selective with respect to the semiconductor material 470 and etch-selective with respect to another material (e.g., an insulator material) provided around the sacrificial material 414 in a later process. In one example, the sacrificial material 414 is or includes an oxide, such as aluminum oxide or another suitable sacrificial material. In one example, the sacrificial material 414 is or includes a metal film such as titanium nitride (TiN) or another metal film. The sacrificial material 414 may be provided using any suitable deposition technique such as atomic layer deposition (ALD), chemical vapor deposition (CVD), plasma enhanced CVD (PECVDP), or other deposition technique. The thickness of the sacrificial material 414 may vary depending on the desired thickness of the conductive material and/or interface material that will be provided in place of the sacrificial material 414 in a later process. In one example, the thickness of the sacrificial material is in a range of 3-15 nanometers, 3-10 nanometers, or 4-8 nanometers. Other thicknesses of the sacrificial material 414 are possible.

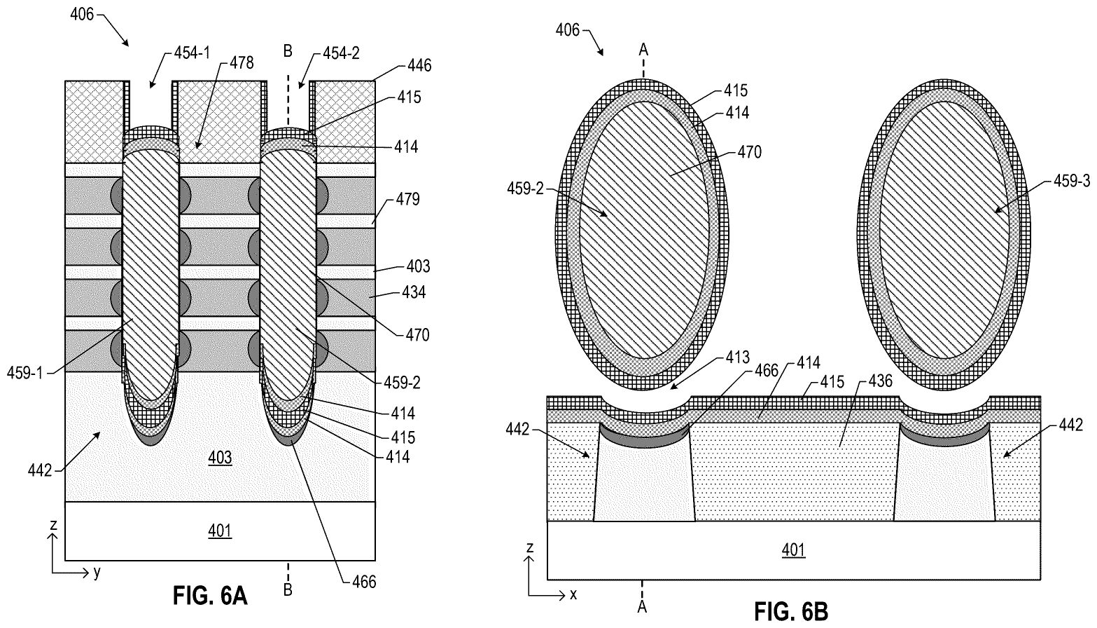

Turning again to FIG. 3, the method 300 continues with a process 306 of providing a second liner including a first insulator material over the first liner. An IC structure 406 of FIGS. 6A-6B illustrates an example result of the process 306. As can be seen in FIG. 6, an insulator material 415 lines the sacrificial material 414 over the semiconductor material 470 of the S/D regions 459. In the example illustrated in FIG. 6, the insulator material 415 forms a conformal liner that wraps around the S/D regions 459 over the sacrificial material 414. In some examples, the insulator material 415 is provided all around the S/D regions 459, e.g., over top portions of the S/D regions 459 in the openings 454 and under bottom portions of the S/D regions 459 (e.g., in the gap 413). Note that in order to not obscure the drawings, the gap 413 is not shown in FIG. 6A after providing the insulator material 415. However, in some examples, a gap 413 may still be present at bottoms of the S/D regions 459 after providing the liner including the insulator material 415 (e.g., FIG. 4B illustrates a gap 413 under the S/D regions after providing the insulator material 415). In some examples, the gap 413 may be filled with the insulator material 415. The insulator material 415 may also be deposited over exposed surfaces under the S/D regions 459 and between nanoribbon stacks, as shown in FIG. 6B, which depicts the insulator material 415 on the sacrificial material 414 over the subfins 442 and under the S/D regions 459-2, 459-3. In one example, the insulator material 415 may also line exposed sidewalls of the openings 454, as shown in FIG. 6A.

The insulator material may be any suitable insulator material such as those described above, e.g., a nitride such as silicon nitride, or other suitable insulator material. The thickness of the insulator material 415 may vary in different embodiments, and a maximum thickness may be limited by other dimensions of the IC structure 406 (e.g., the dimensions of the gap 413 at bottoms of the S/D regions 459). In one example, the liner including the insulator material 415 may have a thickness in a similar range as the thickness of the sacrificial material (e.g., in a range of 3-15 nanometers). However, the insulator material 415 may have a different thickness (e.g., greater than 15 nanometers), and may have a thickness that is smaller than, about the same as, or greater than the thickness of the sacrificial material 414.

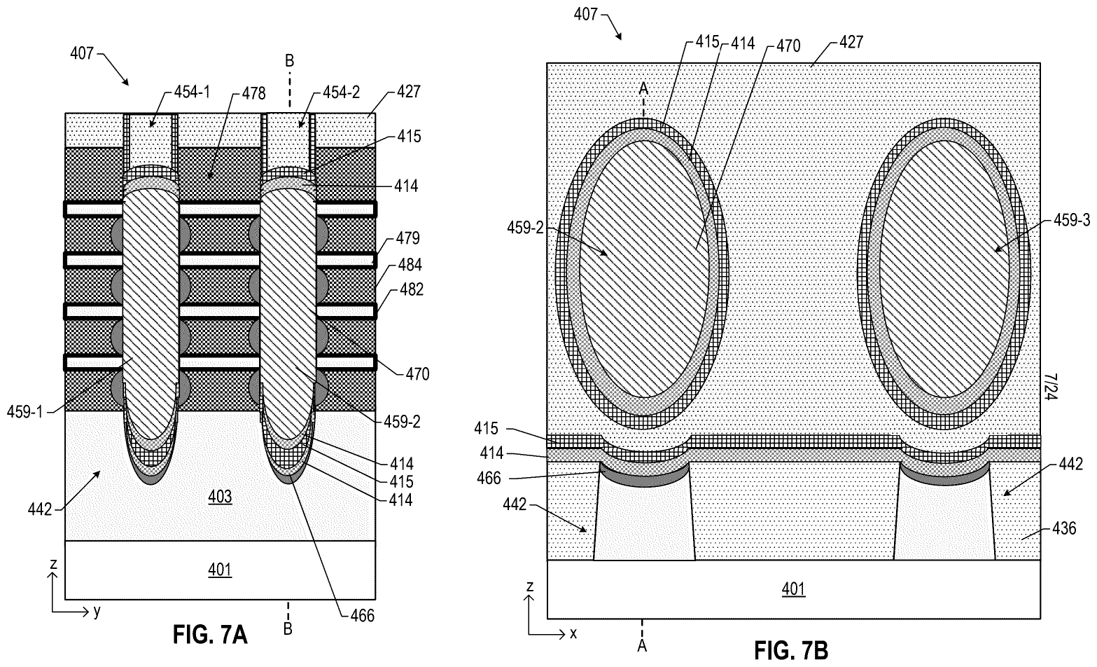

Turning again to FIG. 3, the method 300 continues with a process 308 of providing a second insulator material around the region including the first liner and the second liner. An IC structure 407 of FIGS. 7A-7B illustrates an example result of the process 308. As can be seen in FIG. 7B, an insulator material 427 surrounds the S/D regions 459. The insulator material 427 may, e.g., include any of the ILD materials described above and may have either substantially the same or different material compositions with any other insulator materials in the IC structure 407. In one example, the insulator material 427 may also fill the remaining openings 454 over the S/D regions 459.

The method may also involve the process of removing the dummy gate material and releasing the nanoribbons. Removal of the dummy gate material 446 (e.g., as shown in FIG. 6) may include any suitable etching technique, provided the material of the dummy gate material 446 is sufficiently etch-selective with respect to the other materials of the IC structure 407, in particular, with respect to the semiconductor material 403. Removing the dummy gate exposes the material 434 and the semiconductor material 403 at the sidewalls of the fin. An etch process may then be used to remove the material 434 from the fin, starting from the portions of the material 434 that are exposed by the removal of the dummy gate material 446. As a result of removing the material 434, the nanoribbons of the stack 478 are “released” in that the openings are formed around channel portions of the nanoribbons of the semiconductor material 403. A gate electrode material can then be provided around portions of the nanoribbons 479. FIG. 7A illustrates the IC structure 407 including a gate electrode material 484 around the nanoribbons 479 of the stack 478. The gate electrode material 484 may be the same as, or similar to, the gate electrode material 108 described above with respect to FIG. 1. FIG. 7A further illustrates a gate insulator material 482 that may wrap around the gate regions of the nanoribbons 479 of the stack 478. The gate insulator material 482 may be the same as or similar to the gate insulator material 112 described above with respect to FIG. 1.

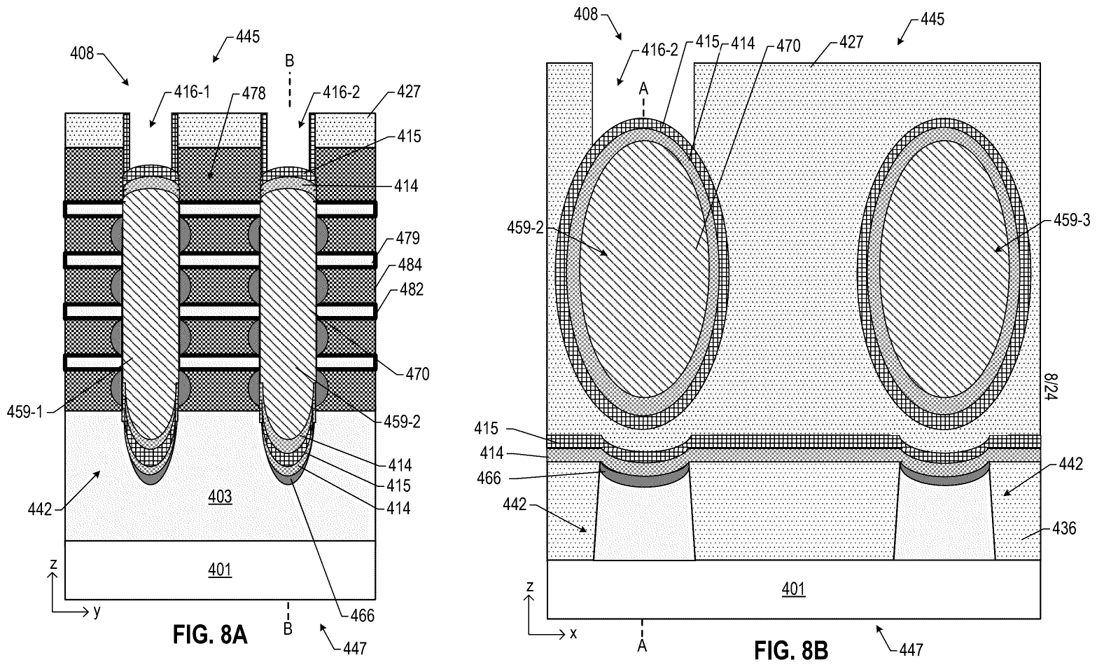

Turning again to FIG. 3, the method 300 continues with a process 310 of forming an opening in the second insulator material over the region. An IC structure 408 of FIGS. 8A-8B illustrates an example result of the process 310. As can be seen in FIG. 8, the openings 416-1, 416-2 are formed over respective S/D regions 459-1, 459-2, and the insulator material 415 is exposed in the openings 416-1, 416-2. Forming the openings 416-1, 416-2 may involve etching the insulator material 427 over the S/D regions 459-1, 459-2. Etching the insulator material 427 may involve, for example, any suitable patterning techniques, such as, but not limited to, photolithographic or electron-beam (e-beam) patterning, possibly in conjunction with a suitable etching technique, e.g., a dry etch, such as e.g., RF reactive ion etch (RIE) or inductively coupled plasma (ICP) RIE. In some embodiments, the etch performed to form the openings 416-1, 416-2 may include an anisotropic etch, using etchants in a form of e.g., chemically active ionized gas (i.e., plasma) using e.g., bromine (Br) and chloride (CI) based chemistries. In some embodiments, during the etch to form the openings 416-1, 416-2, the IC structure 408 may be heated to elevated temperatures, e.g., to temperatures between about room temperature and 200 degrees Celsius, including all values and ranges therein, to promote that byproducts of the etch are made sufficiently volatile to be removed from the surface.

In one example, forming the openings 416-1, 416-2 over the S/D regions 459-1, 459-2 involves only forming openings over N-type or P-type S/D regions. For example, the transistor of FIG. 8 may be one of many transistors on a wafer, including N-type transistors (e.g., NMOS transistors) that include an N-type S/D regions and a P-type channel region and P-type transistors (e.g., PMOS transistors) that include P-type S/D regions and an N-type channel region. In one such example, the process of forming the openings 416-1, 416-2 involves providing a mask over the IC structure 408 to cover either N-type or P-type S/D regions, and with openings over either a source region or a drain region of the other type. In one such example, contact structures for some S/D regions are to be provided from a back side in a later process. For example, the IC structure 408 includes an opening 416-2 over the S/D region 459-2 at a first side 445 of the IC structure 408, but not over the S/D region 459-3 because a contact structure is to be formed from a second side 447 of the IC structure 408 over the S/D region 459-3. In one such example, the first side 445 may be referred to as a front side of the IC structure or a front side of a wafer or substrate over which the IC structure 408 is formed. The second side 447 may be referred to as a back side of the IC structure or a back side of a wafer or substrate over which the IC structure 408 is formed.

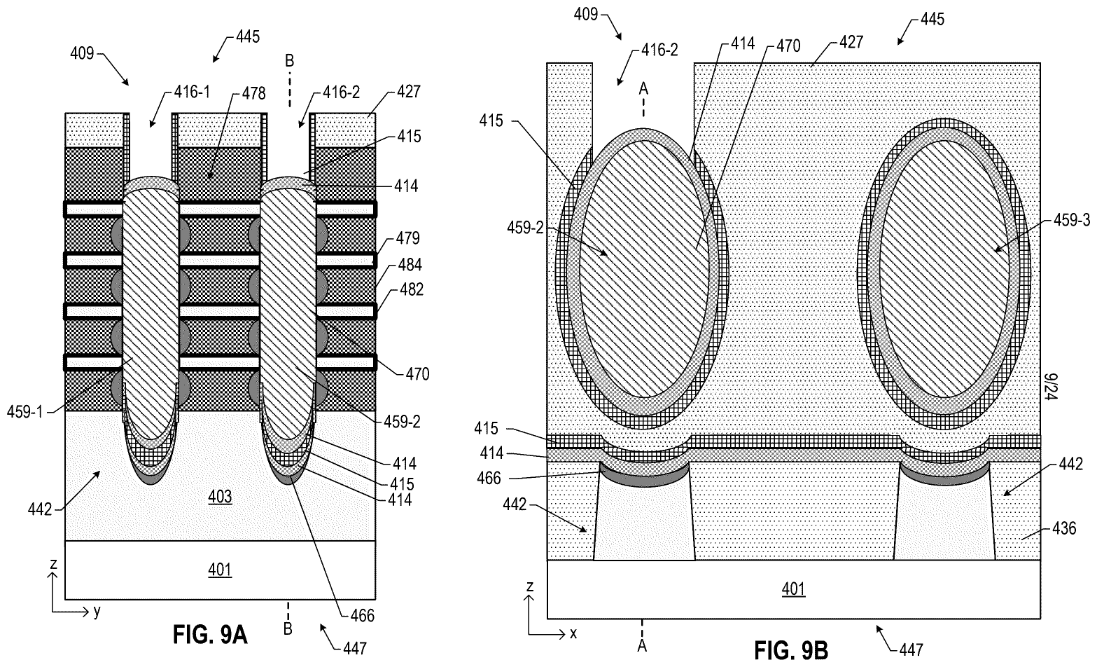

Turning again to FIG. 3, the method 300 continues with a process 312 of removing a portion of the second liner exposed in the opening. An IC structure 409 of FIGS. 9A-9B illustrates an example result of the process 312. As can be seen in FIG. 9, the portion of the insulator material 415 exposed in the openings 416-1, 416-2 is removed. In one example, the insulator material 415 may be removed from bottoms of the openings 416-1, 416-2 over the sacrificial material 414, but not removed from sidewalls of the openings 416-1, 416-2 (as shown in FIG. 9A). Removing the insulator material 415 lining the S/D regions 459-1, 459-2 may be accomplished with any suitable etch technique, such as the techniques discussed above. Removal of the insulator material 415 in the openings 416 exposes the sacrificial material 414 in the openings 416-1, 416-2 (e.g., a portion of the sacrificial material 414 over tops of the S/D regions 459).

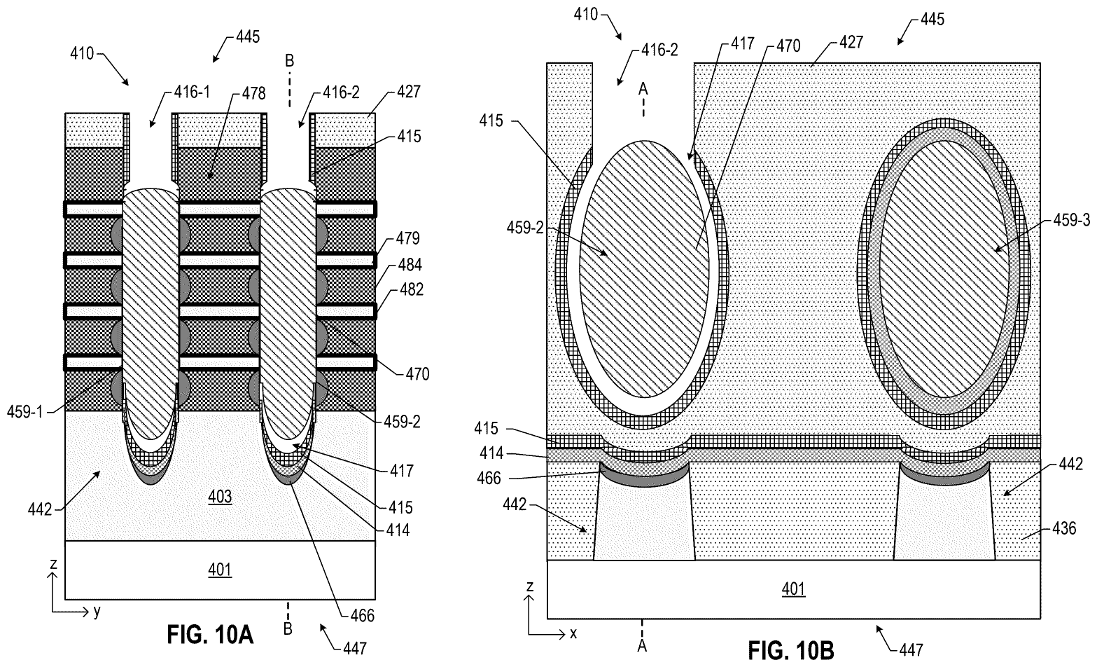

The method 300 continues with a process 314 of removing the first liner, wherein removal of the first liner forms a void between the region and the second liner. An IC structure 410 of FIGS. 10A-10B illustrates an example result of the process 314. As can be seen in FIG. 10, the sacrificial material 414 of the first liner has been removed, leaving a void 417 around the S/D regions 459-1, 459-2 where the sacrificial material 414 was removed. Removing the sacrificial material 414 may involve any suitable etching technique, such as a wet etch technique.

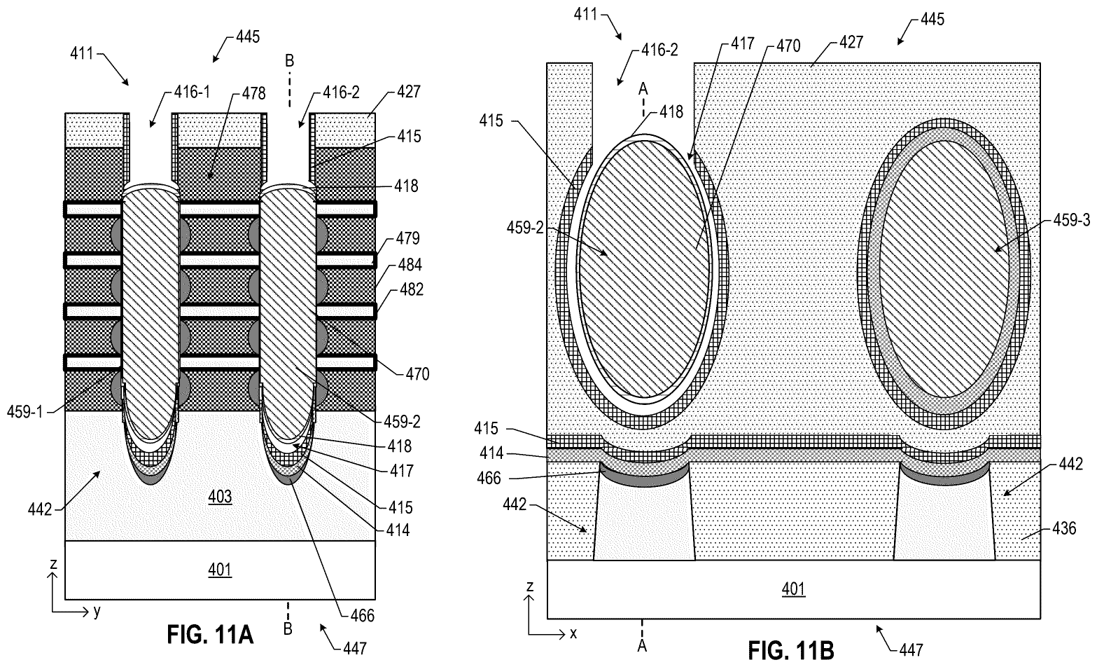

The method 300 continues with a process 316 of providing an interface material on the region in the void. An IC structure 411 of FIGS. 11A-11B illustrates an example result of the process 316. As can be seen in FIG. 11, an interface material 418 lines the semiconductor material 470 of the S/D regions 459-1, 459-2. The interface material 418 may include/be a metal such as titanium which, once deposited, may intermix with the material of the S/D regions 459, e.g., with silicon, forming a compound (e.g., titanium silicide) that may help reduce contact resistance of the S/D contact structures formed over the interface material 418. Providing the interface material may involve, for example, an ion implantation technique (e.g., plasma-immersion ion implantation (PIII)) or other technique suitable for forming a layer of an interface material around the S/D regions 459-1, 459-2. In one example, the thickness of the interface material 418 is sufficient to decrease resistance in the contact structure formed over the S/D regions 459-1, 459-2, but small enough to leave sufficient space for forming a conductive layer over the interface material 418 in the void 417.

Turning again to FIG. 3, the method 300 continues with a process 318 of providing a contact structure including a conductive material on the interface material in the void. An IC structure 412 of FIGS. 12A-12B illustrates an example result of the process 318. The IC structure 412 includes S/D contact structures 494, individually labeled as a first S/D contact structure 494-1 for making electrical contact to the first S/D region 459-1 and a second S/D contact structure 494-2 for making electrical contact to the second S/D region 459-2. The S/D contact structures 494-1, 494-2 include an electrically conductive material 480. The S/D contact structures 494 may be electrically isolated from the gate electrode material 484 and the electrically conductive material of a gate contact between the S/D contact structures 494-1, 494-2 by gate spacers, which may include one or more of spacer materials, diffusion barrier materials, adhesion materials, etc., as known in the art for forming contacts to various components of IC structures. In some embodiments, the gate spacers may include low-k dielectrics and/or any of the ILD materials described above. Optionally, sidewalls of the S/D contact structures 494 may be lined with one or more liners (e.g., the insulator material 415 on sidewalls of the S/D contact openings 416-1, 416-2), which may include, but are not limited to, materials comprising silicon and nitrogen (e.g., silicon nitride), materials comprising silicon and oxygen (e.g., silicon oxide), materials comprising silicon and carbon (e.g., silicon carbide), and/or their composites. Within the sidewalls, the S/D contact structures 494 may be filled with an electrically conductive material 480. In various embodiments, material compositions of the electrically conductive material 480 and the electrically conductive material of a gate contact structure may be substantially the same (e.g., both may include/be tungsten) or different.

In the example illustrated in FIG. 12, the conductive material 480 is not only over the top surfaces of the S/D regions 459-1, 459-2, but also around the S/D regions 459-1, 459-2. For example, the stack 478 of nanoribbons 479 includes first portions 419-1 and second portions 419-2 on either side of the S/D region 459-2 of a doped semiconductor material 470. In one example, the first portions 419-1 are channel regions or channel portions of a first transistor, and the second portions 419-2 are channel regions or channel portions of a second transistor. In the example illustrated in FIG. 12A, the region 459-2 includes a continuous semiconductor material between the first portions 419-1 and the second portions 419-2. In one such example, the continuous semiconductor material of the region 459-2 between the first portions 419-1 and the second portions 419-2 may include a single semiconductor material or different semiconductor materials, but does not include an intervening material that is not a semiconductor material (e.g., does not include an intervening insulator material or metal). Thus, in one such example, the first portions 419-1 of the nanoribbons 479 are in contact with a first side 420-1 of the region 459-2 and the second portions 419-2 of the nanoribbons 479 are in contact with a second side 420-2 of the region 459-2.

In one example, the contact structure 494-2 includes the electrically conductive material 480 over portions of the region 459-2 between the first side 420-1 and the second side 420-2 in the same layers as at least one of the nanoribbons 479 of the stack 478. For example, FIG. 12B depicts the conductive material 480 wrapping around the S/D region 459-2 (in front of the region 459-2 and out of the page, and in back of the region 459-2 and into the page from the perspective shown in FIG. 12B). In the example illustrated in FIG. 12, the conductive material 480 is in the same layers or planes as the nanoribbons 479 of the stack 478. For example, the stack includes a first nanoribbon 479-1 in a first plane substantially parallel to the support 401, a second nanoribbon 479-2 in a second plane substantially parallel to the support 401, a third nanoribbon 479-3 in a third plane substantially parallel to the support 401, and a fourth nanoribbon 479-4 in a fourth plane substantially parallel to the support. In one such example, the region 459-2 includes a first portion 421-1 in the first plane with the first nanoribbon, and a second portion 421-2 in a plane with another nanoribbon stacked over the first nanoribbon (e.g., in the second plane with the second nanoribbon 479-2, in the fourth plane with the fourth nanoribbon 479-4, etc.).

In the illustrated example, the contact structure 494-2 includes a continuous layer of the conductive material over the first portion 421-1 and over the second portion 421-2. For example, the continuous conductive material 480 is over the portions 421-1, 421-2 of the region 459-2 in the same layers or planes as both the top nanoribbon and the bottom nanoribbon (e.g., nanoribbons 479-1 and 479-4) of the stack, as well as over the portions of the region 459-2 in layers above and below the nanoribbons 479 of the stack 478. For example, the continuous layer of the conductive material 480 may be over a portion of the region 459-1 in the same plane as the subfin or in the same plane as another layer under the stack 478, and over a portion of the region 459-2 in the same plane as a layer over the stack. In one example, the continuous conductive material 480 wraps around the region 459-2 so that it is over (e.g., under) a bottom portion and over a top portion of the region 459-1, as shown in FIG. 12B. Thus, the contact structure 494-2 may include a first portion 422-1 over the region 459-2 and over the stack 478 of nanoribbons 479 and a second portion 422-2 that wraps around the region 459-2 and is in contact with the first portion 422-1, to form a metal all-around contact structure 494-2 for the S/D region 459-2. In other examples, the continuous conductive material may only extend part of the way around the region 459-2 (e.g., to the portions of the region adjacent to the nanoribbons 479-2, 479-3, or 479-4). Thus, in some examples, the continuous layer of the conductive material 480 wraps at least partially around the region 459-2 between first channel regions (e.g., the portions 419-1 of the nanoribbons) and second channel regions (e.g., the portions 419-2 of the nanoribbons).

In the example illustrated in FIG. 12, the IC structure 412 includes the interface material 418 between the doped semiconductor material 470 and the conductive material 480. For example, the interface material 418 may include a continuous interface material that wraps around the region 459-2, as shown in FIG. 12. In one example, a liner including the insulator material 415 is over the conductive material 480, and may include a continuous insulator material that wraps around the region 459-2, as shown in FIG. 12. In some examples, layers of the sacrificial material 414 and/or the insulator material 415 may be present below the S/D regions 459. For example, FIG. 12 illustrates a layer of the sacrificial material 414 on subfins 442 (e.g., on the insulator material 466 over the subfin 442), and a layer of the insulator material 415 on the layer of sacrificial material 414. In some examples, the insulator material 427 surrounding the S/D regions may be present between the insulator material 415 lining the S/D region 459-2 and the insulator material 415 lining the subfin, as shown in FIG. 12B.

In the example illustrated in FIG. 12, the S/D contact structures 494-1, 494-2 are coupled with the S/D regions 459-1, 459-2 at a first side 445 of the IC structure 412, and therefore may be referred to as “front-side contacts” or “front-side contact structures.” In some examples, one or more metal-all-around contact structures for an S/D region may be formed form the second side 447 of the IC structure 412.

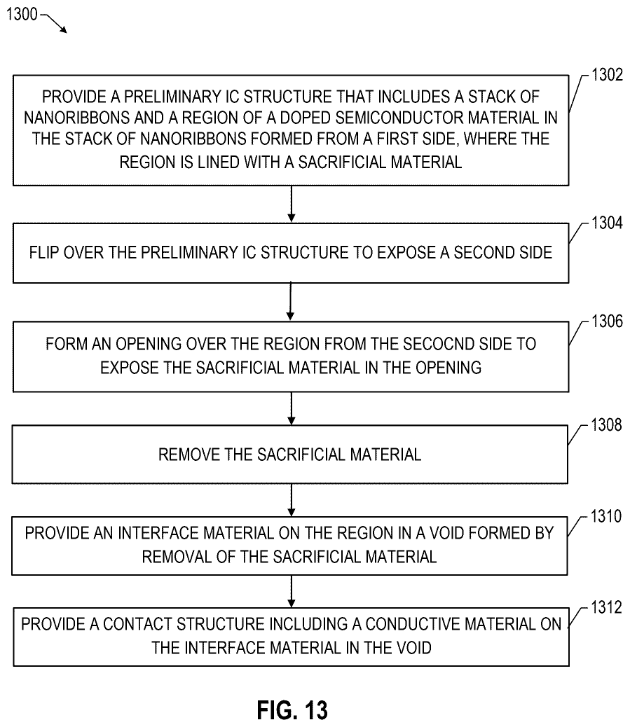

FIG. 13 is a flow diagram of an example method for fabricating an IC structure that includes a back-side metal-all-around contact structure coupled with an S/D region, in accordance with some embodiments. Although the operations of the method of FIG. 13 are illustrated once each and in a particular order, the operations may be performed in any suitable order and repeated as desired. For example, one or more operations may be performed in parallel to fabricate multiple IC structures with a back-side metal-all-around contact structure coupled with an S/D region substantially simultaneously. In another example, the operations may be performed in a different order to reflect the structure of an IC device in which a back-side metal-all-around contact structure coupled with an S/D region will be implemented. In addition, the example fabricating method of FIG. 13 may include other operations not specifically shown in FIG. 13, such as processes discussed above with respect to FIG. 3.

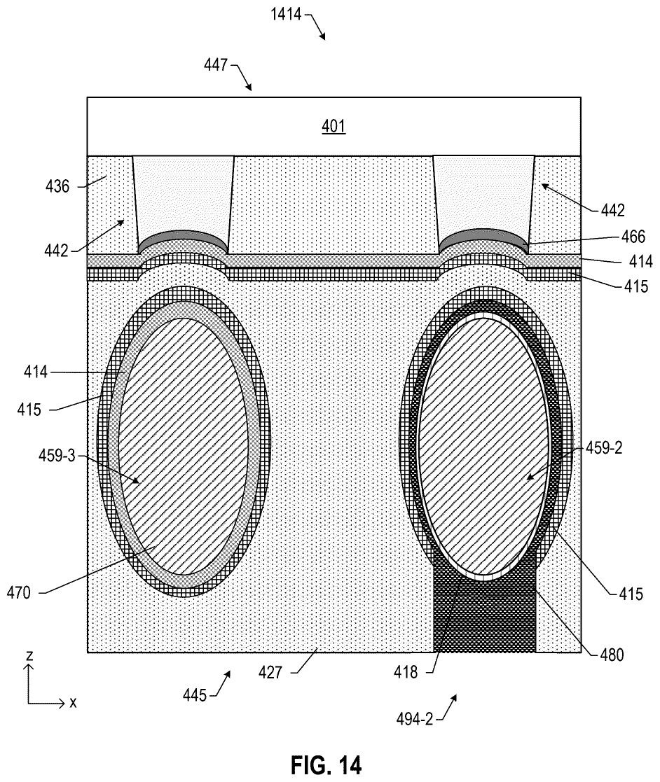

FIGS. 14-20 provide cross-sectional side views at various stages in the fabrication of an example IC structure according to the method of FIG. 13, in accordance with some embodiments.

Turning to FIG. 13, the method 1300 begins with a process 1302 of providing a preliminary IC structure including a stack of nanoribbons and a region of a doped semiconductor material in the stack of nanoribbons, where the region is lined with a sacrificial material, and the process 1304 of flipping over the preliminary IC structure to expose a second side. An IC structure 1414 of FIG. 14 illustrates an example result of the processes 1302 and 1304. The IC structure 1414 is an example of the IC structure 412 of FIG. 12 that has been flipped over to expose the second side 447 of the IC structure. Thus, the IC structure 1414 includes a region 459-3 of a doped semiconductor material, which is formed in a stack of nanoribbons similar to the stack 478 shown in FIG. 12. The IC structure 1414 includes a liner including a sacrificial material 414 around the region 459-3, and a layer of an insulator material 415 over the sacrificial material 414.

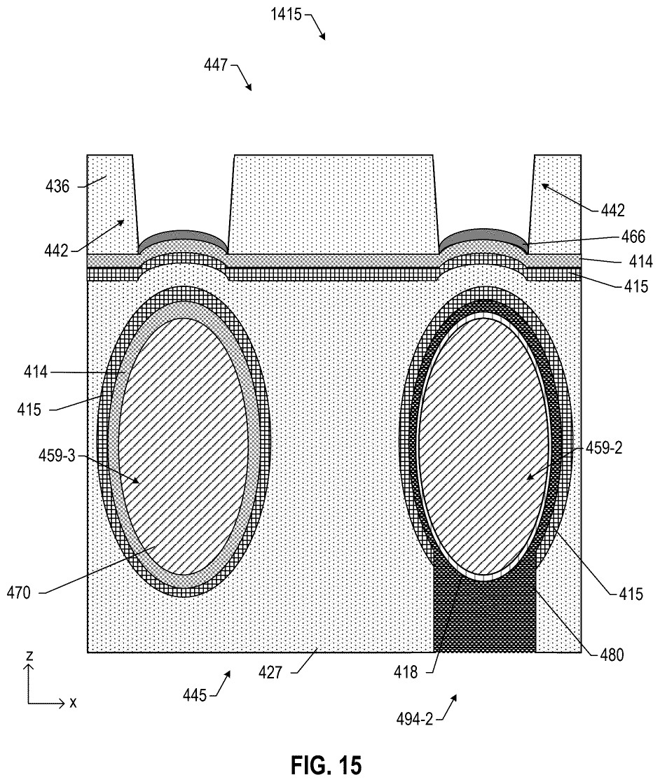

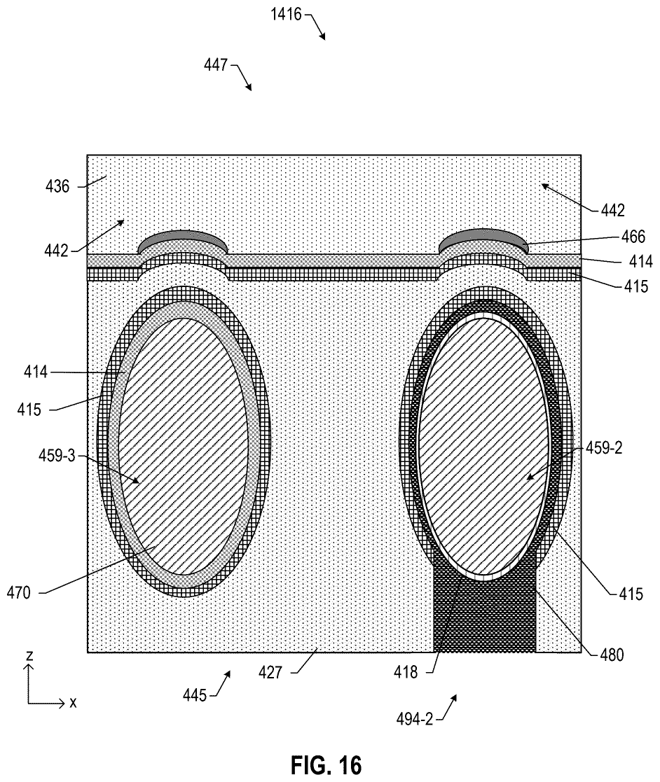

A method similar to the method 300 of FIG. 3 can then be performed from the second side 447 of the IC structure to form back-side metal-all-around contact structures. However, in some examples, prior to performing the processes to provide the contact structure, one or more additional processes may be performed. For example, the method 1300 may involve removing one or more materials over the second side 447 of the IC structure, such as the support 401 and the semiconductor material 403 (e.g., some or all of the material of the subfin 442 under the S/D region 459-3). Removing the semiconductor material 403 may include etching the semiconductor material 403, e.g., using anisotropic etching or another etching technique, without substantially etching the insulator material 436. FIG. 15 illustrates an example IC structure 1415 in which the support 401 and the semiconductor material 403 of the subfins 442 have has been removed. In one example, after removing the semiconductor material 403 of the subfins 442, the area of the subfins 442 can be filled with an insulator material. the FIG. 16 illustrates an example IC structure 1416 in which the openings formed when the semiconductor material 403 was removed have been filled with an insulator material 436. FIG. 16 illustrates an example in which the subfins 442 are filled with the same insulator material as the insulator material 436 surrounding the S/D regions 459, however, the subfins 442 may be filled with the same or a different insulator material.

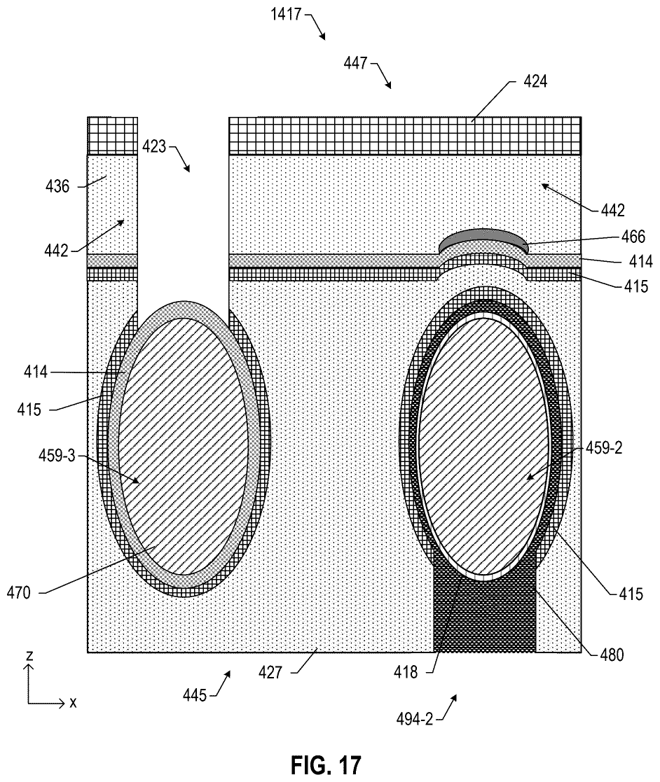

The method 1300 continues with a process 1306 of forming an opening over the region from the second side to expose the sacrificial material in the opening. An IC structure 1417 of FIG. 17 illustrates an example result of the process 1306. As can be seen in FIG. 17, the IC structure 1417 includes an opening 423 at the second side 447 of the IC structure 1417 over the S/D region 459-3. Forming the opening 423 may involve multiple processes, including forming a mask 424 over the second side 447, where the mask has an opening over the S/D region 459-3 and covers other features, such as the S/D region 459-2 that is coupled with a front-side contact structure 494-2. In the example illustrated in FIG. 17, forming the opening 423 involves etching the insulator material 436, the sacrificial material 414 over the subfin region, the insulator material 415 over the subfin region, and removing a portion of the insulator material 415 over the S/D region 459-3. Removing the portion of the insulator material 415 may involve a process similar to the process 312 of FIG. 3, discussed above. Removing the portion of the insulator material 415 over the S/D region 459-3 exposes the sacrificial material 414 lining the S/D region 459-3 (e.g., the sacrificial material 414 lining a bottom of the S/D region 459-3).

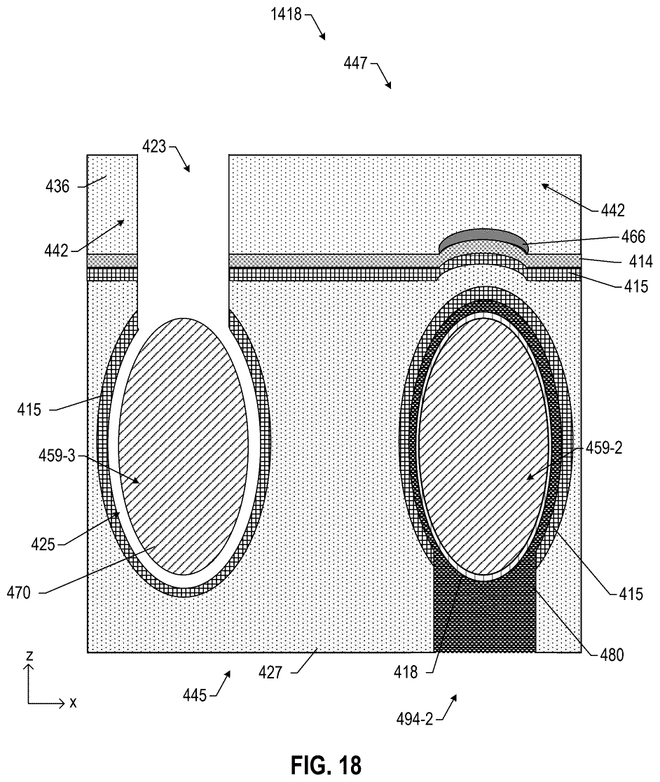

The method 1300 continues with a process 1308 of removing the sacrificial material exposed in the opening. An IC structure 1418 of FIG. 18 illustrates an example result of the process 1308. As can be seen in FIG. 18, the sacrificial material 414 lining the S/D region 459-3 has been removed, leaving a void 425 around the S/D region 459-3 where the sacrificial material 414 was removed. Removing the sacrificial material 414 may involve a process similar to the process 314 of FIG. 3, discussed above. In some examples, the mask 424 may also be removed from over the second side 447 of the IC structure 1418.

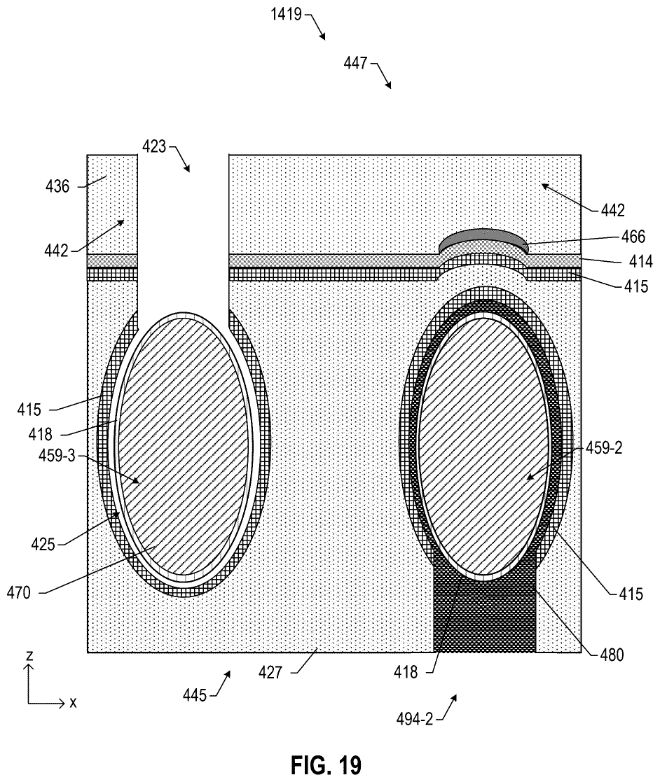

The method 1300 continues with a process 1310 of providing an interface material on the region in a void formed by removal of the sacrificial material. An IC structure 1419 of FIG. 19 illustrates an example result of the process 1310. As can be seen in FIG. 19, an interface material 418 lines the semiconductor material 470 of the S/D region 459-3. Providing the interface material 418 may involve a process similar to the process 316 of FIG. 3, discussed above.

The method 1300 continues with a process 1312 of providing a contact structure including a conductive material on the interface material in the void. An IC structure 1420 of FIG. 20 illustrates an example result of the process 1312. As can be seen in FIG. 20, the IC structure 1420 includes a back-side contact structure 494-3 coupled with the S/D region 459-3. The contact structure 494-3 may be substantially the same as the contact structure 494-2, except formed from the back side of the IC structure 1420, and thus coupling with conductive interconnects from the opposite side of the IC structure 1420 from the contact structure 494-2.

Interconnect layers may be formed over the device region of the IC structure 1420 to connect the contact structures 494 with other conductive elements. For example, the IC structure 1420 includes the device region 428, a first interconnect layer 429 formed over a first side 445 of the device region 428, and a second interconnect layer 430 formed over a second side 447 of the device region 428. Additional interconnect layers may be present above the interconnect layers 429, 430. A collection of interconnect layers may be referred to as a “metallization stack” of the IC structure 1420. Interchangeably, the metallization stack may be referred to as the “back end of line (BEOL) layer(s)” of the IC structure 1420, while the device region 428 may be referred to as the “front end of line (FEOL) layer(s)” of the IC structure 1420.

Electrical signals, such as power and/or input/output (I/O) signals, may be routed to and/or from the devices (e.g., the transistors) of the device region 428 through one or more interconnect layers disposed on the device region 428 (illustrated in FIG. 20 as interconnect layers 429 and 430). For example, electrically conductive features of the device region 428 (e.g., the electrically conductive material 480 of the S/D contact structures 494) may be electrically coupled with the interconnect structures 455 of the interconnect layers 429 and 430. The interconnect structures 455 may be arranged within the interconnect layers of the metallization stack to route electrical signals according to a wide variety of designs (in particular, the arrangement is not limited to the particular configuration of interconnect structures 455 depicted in FIG. 20). Although a particular number of interconnect layers 429 and 430 is depicted in FIG. 20, embodiments of the present disclosure include IC structures having more or fewer interconnect layers than depicted.

In some embodiments, the interconnect structures 455 may include conductive lines and/or conductive vias filled with an electrically conductive material such as a metal. The lines may be arranged to route electrical signals in a direction of a plane that is substantially parallel with a surface of the support upon which the device region 428 is formed. For example, the lines may route electrical signals in a direction in and out of the page from the perspective of FIG. 20. The vias may be arranged to route electrical signals in a direction of a plane that is substantially perpendicular to the surface of the support upon which the device region 428 is formed. In some embodiments, the vias may electrically couple lines of different interconnect layers of the metallization stack together.

Thus, the methods 300 and 1300 of FIGS. 3 and 13 are example methods for forming IC structures with metal-all-around contact structures coupled with S/D regions. Performing the method 300 of FIG. 3 and/or the method 1300 of FIG. 13 may result in features in the final IC structures that are characteristic of the use of the methods 300 and/or 1300. For example, one such feature is illustrated in the IC structure 1420 shown in FIG. 12, which shows a region (e.g., the S/D region 459-2) that is either a source or drain region of a transistor, where the region includes first portions in contact with the semiconductor material of the nanoribbons on either side of the region (e.g., nanoribbon-facing portions), second portions between the first portions (e.g., protruding away from the nanoribbons in and out of the page as shown in FIG. 12), and a continuous conductive material 480 around the second portions of the region. The IC structure 1420 also includes a continuous interface material 418 around the second portions of the region 459-2 between the continuous conductive material 480 and the region 459-2. FIG. 20 also depicts an IC structure 1420 with both front-side and back-side metal-all-around S/D contact structures (e.g., contact structures 494-2 and 494-3). Although the IC structure 1420 of FIG. 20 depicts one S/D region coupled with a front-side contact structure and another S/D region coupled with a back-side contact structure, both S/D regions may be coupled with contact structures from either a front or back side of the IC structure.

IC devices/structures that include a metal-all-around contact structure coupled with an S/D region as described herein (e.g., as described with reference to FIGS. 3-20) may be used to implement any suitable components. For example, in various embodiments, IC structures described herein may be part of one or more of: a central processing unit, a memory device (e.g., a high-bandwidth memory device), a memory cell, a logic circuit, input/output circuitry, a field programmable gate array (FPGA) component such as an FPGA transceiver or an FPGA logic, a power delivery circuitry, an amplifier (e.g., a III-V amplifier), Peripheral Component Interconnect Express (PCIE) circuitry, Double Data Rate (DDR) transfer circuitry, a computing device (e.g., a wearable or a handheld computing device), etc.

The IC devices and structures disclosed herein, e.g., the IC structures 100, 200, 404-412, 1414-1420 or any variations thereof, may be included in any suitable electronic component.

FIGS. 21-24 illustrate various examples of apparatuses that may include any of the IC devices/structures disclosed herein.

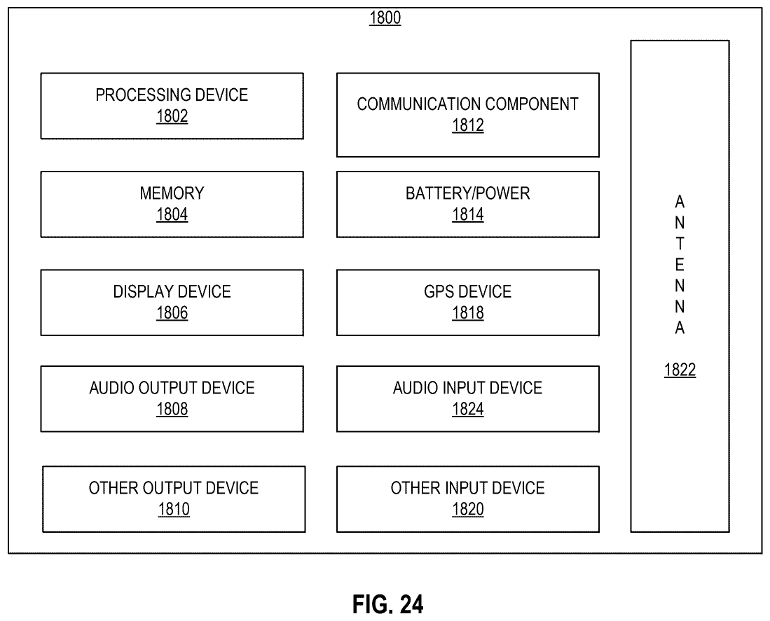

FIG. 21 is a top view of a wafer 1500 and dies 1502 that may include one or more IC structures in accordance with any of the embodiments disclosed herein. The wafer 1500 may be composed of semiconductor material and may include one or more dies 1502 having IC structures formed on a surface of the wafer 1500. Each of the dies 1502 may be a repeating unit of a semiconductor product that includes any suitable IC. After the fabrication of the semiconductor product is complete, the wafer 1500 may undergo a singulation process in which the dies 1502 are separated from one another to provide discrete “chips” of the semiconductor product. The die 1502 may include one or more IC structures as described herein (e.g., any of the IC structures 100, 200, 404-412, 1414-1420, described herein), one or more transistors (e.g., nanoribbon transistors of the IC structures 100, 200, 404-412, 1414-1420) and/or supporting circuitry to route electrical signals to the transistors, as well as any other IC components. In some embodiments, the wafer 1500 or the die 1502 may include a memory device (e.g., a random-access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 1502. For example, a memory array formed by multiple memory devices may be formed on a same die 1502 as a processing device (e.g., the processing device 1802 of FIG. 24) or other logic that is configured to store information in the memory devices or execute instructions stored in the memory array.

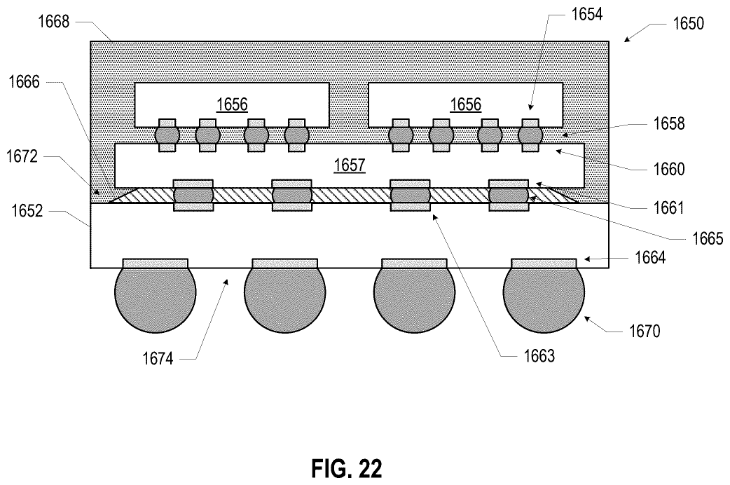

FIG. 22 is a side, cross-sectional view of an example IC package 1650 that may include one or more IC structures in accordance with any of the embodiments disclosed herein (e.g., any of the IC structures 100, 200, 404-412, 1414-1420, described herein). In some embodiments, the IC package 1650 may be a system-in-package (SiP).

The package substrate 1652 may be formed of a dielectric material (e.g., a ceramic, a buildup film, an epoxy film having filler particles therein, glass, an organic material, an inorganic material, combinations of organic and inorganic materials, embedded portions formed of different materials, etc.), and may have conductive pathways extending through the dielectric material between the face 1672 and the face 1674, or between different locations on the face 1672, and/or between different locations on the face 1674. These conductive pathways may take the form of any of the interconnects discussed above with reference to FIG. 21.

The package substrate 1652 may include conductive contacts 1663 that are coupled to conductive pathways (not shown) through the package substrate 1652, allowing circuitry within the dies 1656 and/or the interposer 1657 to electrically couple to various ones of the conductive contacts 1664 (or to devices included in the package substrate 1652, not shown).

The IC package 1650 may include an interposer 1657 coupled to the package substrate 1652 via conductive contacts 1661 of the interposer 1657, first-level interconnects 1665, and the conductive contacts 1663 of the package substrate 1652. The first-level interconnects 1665 illustrated in FIG. 22 are solder bumps, but any suitable first-level interconnects 1665 may be used. In some embodiments, no interposer 1657 may be included in the IC package 1650; instead, the dies 1656 may be coupled directly to the conductive contacts 1663 at the face 1672 by first-level interconnects 1665. More generally, one or more dies 1656 may be coupled to the package substrate 1652 via any suitable structure (e.g., a silicon bridge, an organic bridge, one or more waveguides, one or more interposers, wirebonds, etc.).

The IC package 1650 may include one or more dies 1656 coupled to the interposer 1657 via conductive contacts 1654 of the dies 1656, first-level interconnects 1658, and conductive contacts 1660 of the interposer 1657. The conductive contacts 1660 may be coupled to conductive pathways (not shown) through the interposer 1657, allowing circuitry within the dies 1656 to electrically couple to various ones of the conductive contacts 1661 (or to other devices included in the interposer 1657, not shown). The first-level interconnects 1658 illustrated in FIG. 22 are solder bumps, but any suitable first-level interconnects 1658 may be used. As used herein, a “conductive contact” may refer to a portion of conductive material (e.g., metal) serving as an interface between different components; conductive contacts may be recessed in, flush with, or extending away from a surface of a component, and may take any suitable form (e.g., a conductive pad or socket).

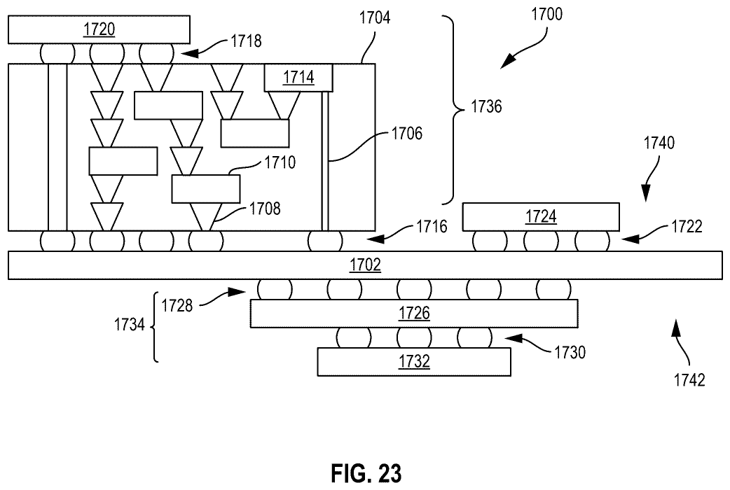

In some embodiments, an underfill material 1666 may be disposed between the package substrate 1652 and the interposer 1657 around the first-level interconnects 1665, and a mold compound 1668 may be disposed around the dies 1656 and the interposer 1657 and in contact with the package substrate 1652. In some embodiments, the underfill material 1666 may be the same as the mold compound 1668. Example materials that may be used for the underfill material 1666 and the mold compound 1668 are epoxy mold materials, as suitable. Second-level interconnects 1670 may be coupled to the conductive contacts 1664. The second-level interconnects 1670 illustrated in FIG. 22 are solder balls (e.g., for a ball grid array arrangement), but any suitable second-level interconnects 1670 may be used (e.g., pins in a pin grid array arrangement or lands in a land grid array arrangement). The second-level interconnects 1670 may be used to couple the IC package 1650 to another component, such as a circuit board (e.g., a motherboard), an interposer, or another IC package, as known in the art and as discussed below with reference to FIG. 23.

The dies 1656 may take the form of any of the embodiments of the die 1502 discussed herein. In embodiments in which the IC package 1650 includes multiple dies 1656, the IC package 1650 may be referred to as a multi-chip package (MCP). The dies 1656 may include circuitry to perform any desired functionality. For example, or more of the dies 1656 may be logic dies (e.g., silicon-based dies), and one or more of the dies 1656 may be memory dies (e.g., high-bandwidth memory).

Although the IC package 1650 illustrated in FIG. 22 is a flip chip package, other package architectures may be used. For example, the IC package 1650 may be a ball grid array (BGA) package, such as an embedded wafer-level ball grid array (eWLB) package. In another example, the IC package 1650 may be a wafer-level chip scale package (WLCSP) or a panel fanout (FO) package. Although two dies 1656 are illustrated in the IC package 1650 of FIG. 22, an IC package 1650 may include any desired number of dies 1656. An IC package 1650 may include additional passive components, such as surface-mount resistors, capacitors, and inductors disposed on the first face 1672 or the second face 1674 of the package substrate 1652, or on either face of the interposer 1657. More generally, an IC package 1650 may include any other active or passive components known in the art.

FIG. 23 is a side, cross-sectional view of an IC device assembly 1700 that may include one or more IC packages or other electronic components (e.g., a die) including one or more IC devices in accordance with any of the embodiments disclosed herein. The IC device assembly 1700 includes a number of components disposed on a circuit board 1702 (which may be, e.g., a motherboard). The IC device assembly 1700 includes components disposed on a first face 1740 of the circuit board 1702 and an opposing second face 1742 of the circuit board 1702; generally, components may be disposed on one or both faces 1740 and 1742. Any of the IC packages discussed below with reference to the IC device assembly 1700 may take the form of any of the embodiments of the IC package 1650 discussed above with reference to FIG. 22 (e.g., may include one or more the IC structures 100, 200, 404-412, 1414-1420).

In some embodiments, the circuit board 1702 may be a PCB including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 1702. In other embodiments, the circuit board 1702 may be a non-PCB substrate.

The IC device assembly 1700 illustrated in FIG. 23 includes a package-on-interposer structure 1736 coupled to the first face 1740 of the circuit board 1702 by coupling components 1716. The coupling components 1716 may electrically and mechanically couple the package-on-interposer structure 1736 to the circuit board 1702, and may include solder balls (as shown in FIG. 23), male and female portions of a socket, an adhesive, an underfill material, and/or any other suitable electrical and/or mechanical coupling structure.

The package-on-interposer structure 1736 may include an IC package 1720 coupled to a package interposer 1704 by coupling components 1718. The coupling components 1718 may take any suitable form for the application, such as the forms discussed above with reference to the coupling components 1716. Although a single IC package 1720 is shown in FIG. 23, multiple IC packages may be coupled to the package interposer 1704; indeed, additional interposers may be coupled to the package interposer 1704. The package interposer 1704 may provide an intervening substrate used to bridge the circuit board 1702 and the IC package 1720. The IC package 1720 may be or include, for example, a die (the die 1502 of FIG. 21), an IC device (e.g., any of the IC structures 100, 200, and 404-410, described herein, or any combination of such IC devices), or any other suitable component. Generally, the package interposer 1704 may spread a connection to a wider pitch or reroute a connection to a different connection. For example, the package interposer 1704 may couple the IC package 1720 (e.g., a die) to a set of BGA conductive contacts of the coupling components 1716 for coupling to the circuit board 1702. In the embodiment illustrated in FIG. 23, the IC package 1720 and the circuit board 1702 are attached to opposing sides of the package interposer 1704; in other embodiments, the IC package 1720 and the circuit board 1702 may be attached to a same side of the package interposer 1704. In some embodiments, three or more components may be interconnected by way of the package interposer 1704.

In some embodiments, the package interposer 1704 may be formed as a PCB, including multiple metal layers separated from one another by layers of dielectric material and interconnected by electrically conductive vias. In some embodiments, the package interposer 1704 may be formed of an epoxy resin, a fiberglass-reinforced epoxy resin, an epoxy resin with inorganic fillers, a ceramic material, or a polymer material such as polyimide. In some embodiments, the package interposer 1704 may be formed of alternate rigid or flexible materials that may include the same materials described above for use in a semiconductor substrate, such as silicon, germanium, and other group III-V and group IV materials. The package interposer 1704 may include metal lines 1710 and vias 1708, including but not limited to through-silicon vias (TSVs) 1706. The package interposer 1704 may further include embedded devices 1714, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as RF devices, power amplifiers, power management devices, antennas, arrays, sensors, and microelectromechanical systems (MEMS) devices may also be formed on the package interposer 1704. The package-on-interposer structure 1736 may take the form of any of the package-on-interposer structures known in the art.

The IC device assembly 1700 may include an IC package 1724 coupled to the first face 1740 of the circuit board 1702 by coupling components 1722. The coupling components 1722 may take the form of any of the embodiments discussed above with reference to the coupling components 1716, and the IC package 1724 may take the form of any of the embodiments discussed above with reference to the IC package 1720.

The IC device assembly 1700 illustrated in FIG. 23 includes a package-on-package structure 1734 coupled to the second face 1742 of the circuit board 1702 by coupling components 1728. The package-on-package structure 1734 may include an IC package 1726 and an IC package 1732 coupled together by coupling components 1730 such that the IC package 1726 is disposed between the circuit board 1702 and the IC package 1732. The coupling components 1728 and 1730 may take the form of any of the embodiments of the coupling components 1716 discussed above, and the IC packages 1726 and 1732 may take the form of any of the embodiments of the IC package 1720 discussed above. The package-on-package structure 1734 may be configured in accordance with any of the package-on-package structures known in the art.

FIG. 24 is a block diagram of an example electrical device 1800 that may include one or more IC structures 100 in accordance with any of the embodiments disclosed herein. For example, any suitable ones of the components of the electrical device 1800 may include one or more of the IC device assemblies 1700, IC packages 1650, or dies 1502 disclosed herein. A number of components are illustrated in FIG. 24 as included in the electrical device 1800, but any one or more of these components may be omitted or duplicated, as suitable for the application. In some embodiments, some or all of the components included in the electrical device 1800 may be attached to one or more motherboards. In some embodiments, some or all of these components are fabricated onto a single system-on-a-chip (SoC) die.

Additionally, in various embodiments, the electrical device 1800 may not include one or more of the components illustrated in FIG. 24, but the electrical device 1800 may include interface circuitry for coupling to the one or more components. For example, the electrical device 1800 may not include a display device 1806, but may include display device interface circuitry (e.g., a connector and driver circuitry) to which a display device 1806 may be coupled. In another set of examples, the electrical device 1800 may not include an audio input device 1824 or an audio output device 1808, but may include audio input or output device interface circuitry (e.g., connectors and supporting circuitry) to which an audio input device 1824 or audio output device 1808 may be coupled.

The electrical device 1800 may include a processing device 1802 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 1802 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices. The electrical device 1800 may include a memory 1804, which may itself include one or more memory devices such as volatile memory (e.g., dynamic RAM (DRAM)), nonvolatile memory (e.g., read-only memory (ROM)), flash memory, solid state memory, and/or a hard drive. In some embodiments, the memory 1804 may include memory that shares a die with the processing device 1802. This memory may be used as cache memory and may include embedded dynamic RAM (eDRAM) or spin transfer torque magnetic RAM (STT-MRAM).

In some embodiments, the electrical device 1800 may include a communication chip 1812 (e.g., one or more communication chips). For example, the communication chip 1812 may be configured for managing wireless communications for the transfer of data to and from the electrical device 1800. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

The communication chip 1812 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 1812 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 1812 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 1812 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 1812 may operate in accordance with other wireless protocols in other embodiments. The electrical device 1800 may include an antenna 1822 to facilitate wireless communications and/or to receive other wireless communications (such as AM or FM radio transmissions).

In some embodiments, the communication chip 1812 may manage wired communications, such as electrical, optical, or any other suitable communication protocols (e.g., the Ethernet). As noted above, the communication chip 1812 may include multiple communication chips. For instance, a first communication chip 1812 may be dedicated to shorter-range wireless communications such as Wi-Fi or Bluetooth, and a second communication chip 1812 may be dedicated to longer-range wireless communications such as global positioning system (GPS), EDGE, GPRS, CDMA, WiMAX, LTE, EV-DO, or others. In some embodiments, a first communication chip 1812 may be dedicated to wireless communications, and a second communication chip 1812 may be dedicated to wired communications.

The electrical device 1800 may include battery/power circuitry 1814. The battery/power circuitry 1814 may include one or more energy storage devices (e.g., batteries or capacitors) and/or circuitry for coupling components of the electrical device 1800 to an energy source separate from the electrical device 1800 (e.g., AC line power).

The electrical device 1800 may include a display device 1806 (or corresponding interface circuitry, as discussed above). The display device 1806 may include any visual indicators, such as a heads-up display, a computer monitor, a projector, a touchscreen display, a liquid crystal display (LCD), a light-emitting diode display, or a flat panel display.

The electrical device 1800 may include an audio output device 1808 (or corresponding interface circuitry, as discussed above). The audio output device 1808 may include any device that generates an audible indicator, such as speakers, headsets, or earbuds.

The electrical device 1800 may include an audio input device 1824 (or corresponding interface circuitry, as discussed above). The audio input device 1824 may include any device that generates a signal representative of a sound, such as microphones, microphone arrays, or digital instruments (e.g., instruments having a musical instrument digital interface (MIDI) output).

The electrical device 1800 may include a GPS device 1818 (or corresponding interface circuitry, as discussed above). The GPS device 1818 may be in communication with a satellite-based system and may receive a location of the electrical device 1800, as known in the art.

The electrical device 1800 may include an other output device 1810 (or corresponding interface circuitry, as discussed above). Examples of the other output device 1810 may include an audio codec, a video codec, a printer, a wired or wireless transmitter for providing information to other devices, or an additional storage device.

The electrical device 1800 may include an other input device 1820 (or corresponding interface circuitry, as discussed above). Examples of the other input device 1820 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The electrical device 1800 may have any desired form factor, such as a handheld or mobile electrical device (e.g., a cell phone, a smart phone, a mobile internet device, a music player, a tablet computer, a laptop computer, a netbook computer, an ultrabook computer, a personal digital assistant (PDA), an ultra mobile personal computer, etc.), a desktop electrical device, a server device or other networked computing component, a printer, a scanner, a monitor, a set-top box, an entertainment control unit, a vehicle control unit, a digital camera, a digital video recorder, or a wearable electrical device. In some embodiments, the electrical device 1800 may be any other electronic device that processes data.

The following paragraphs provide various examples of the embodiments disclosed herein.
Example 1 provides an IC structure, including a region of a doped semiconductor material; a stack of nanoribbons of a semiconductor material including first portions and second portions on either side of the region, where the first portions are in contact with a first side of the region and the second portions are in contact with a second side of the region (e.g., where the second side is opposite the first side); and a conductive material over a portion of the region between the first side and the second side in a same layer as at least one of the nanoribbons of the stack.
Example 2 provides the IC structure of example 1, where: the stack of nanoribbons includes a first nanoribbon (e.g., a bottom nanoribbon) and a second nanoribbon (e.g., a top nanoribbon) stacked over the bottom nanoribbon; and the conductive material is a continuous conductive material over the portions of the region in same layers as the first nanoribbon and the second nanoribbon.
Example 3 provides the IC structure of examples 1 or 2, where: the conductive material is a continuous conductive material over the portions of the region in layers above and below the nanoribbons of the stack.
Example 4 provides the IC structure of any one of examples 1-3, where: the conductive material is a continuous conductive material that wraps around the region.
Example 5 provides the IC structure of any one of examples 1-4, further including an interface material between the doped semiconductor material and the conductive material.
Example 6 provides the IC structure of example 5, where: the interface material is a continuous interface material that wraps around the region.
Example 7 provides the IC structure of any one of examples 1-5, further including a liner including an insulator material over the conductive material.
Example 8 provides the IC structure of example 7, where: the liner includes a continuous insulator material that wraps around the region.
Example 9 provides the IC structure of example 7, where: a thickness of the conductive material between the liner and the region is in a range of 3-15 nanometers.
Example 10 provides the IC structure of any one of examples 1-9, further including a contact structure including: a first portion of the conductive material in a layer over the stack of nanoribbons, and a second portion that includes the conductive material over the portions of the region, where the second portion wraps around the region and is in contact with the first portion.
Example 11 provides an IC structure, including a stack of nanoribbons, where the stack includes a first nanoribbon in a first plane and a second nanoribbon in a second plane over the first nanoribbon, and where the nanoribbons include first channel regions of a first transistor and second channel regions of a second transistor; a region including a continuous doped semiconductor material between the first channel regions and the second channel regions, where the region includes a first portion in the first plane and a second portion in the second plane; and a contact structure coupled with the region, where the contact structure includes a continuous layer of conductive material over the first portion and over the second portion of the region.
Example 12 provides the IC structure of example 11, where: the region includes a third portion in a third plane under the nanoribbons of the stack and a fourth portion in a fourth plane over the nanoribbons of the stack; and the continuous layer of conductive material is over the third portion and over the fourth portion.
Example 13 provides the IC structure of examples 11 or 12, where: the continuous layer of conductive material wraps around the region between the first channel regions and the second channel regions.
Example 14 provides the IC structure of any one of examples 11-13, further including a layer of interface material between the region and the continuous layer of conductive material.
Example 15 provides the IC structure of example 14, where: the interface material is a continuous interface material that wraps around the region between the first channel regions and the second channel regions.
Example 16 provides the IC structure of any one of examples 11-15, further including a first insulator material surrounding the first portion and the second portion of the region; and a layer of a second insulator material between the first insulator material and the continuous layer of conductive material.
Example 17 provides the IC structure of example 16, where: the layer of the second insulator material is a continuous layer of the second insulator material that wraps around the region between the first channel regions and the second channel regions.
Example 18 provides the IC structure of any one of examples 11-17, where: the contact structure includes a conductive structure in a layer over the stack of nanoribbons, where the conductive structure is in contact with the continuous layer of conductive material.
Example 19 provides an IC structure, including a stack of nanoribbons of a semiconductor material; a region in the stack of nanoribbons that is either a source region or a drain region of a transistor, where the region includes first portions in contact with the semiconductor material of the nanoribbons on either side of the region, and second portions between the first portions; and a continuous conductive material lining the second portions of the region.
Example 20 provides the IC structure of example 19, further including a continuous interface material lining the second portions of the region between the continuous conductive material and the region.
Example 21 provides an IC structure according to any one of examples 1-20, where the IC structure includes or is a part of a central processing unit.
Example 22 provides an IC structure according to any one of examples 1-21, where the IC structure includes or is a part of a memory device.
Example 23 provides an IC structure according to any one of examples 1-22, where the IC structure includes or is a part of a logic circuit.
Example 24 provides an IC structure according to any one of examples 1-23, where the IC structure includes or is a part of input/output circuitry.
Example 25 provides an IC structure according to any one of examples 1-24, where the IC structure includes or is a part of a field programmable gate array transceiver.
Example 26 provides an IC structure according to any one of examples 1-25, where the IC structure includes or is a part of a field programmable gate array logic.
Example 27 provides an IC structure according to any one of examples 1-26, where the IC structure includes or is a part of a power delivery circuitry.
Example 28 provides an IC package that includes an IC die including an IC structure according to any one of examples 1-27; and a further IC component, coupled to the IC die.
Example 29 provides an IC package according to example 28 where the further IC component includes a package substrate.
Example 30 provides an IC package according to example 28, where the further IC component includes an interposer.
Example 31 provides an IC package according to example 28, where the further IC component includes a further IC die.
Example 32 provides a computing device that includes a carrier substrate and an IC structure coupled to the carrier substrate, where the IC structure is an IC structure according to any one of examples 1-27, or the IC structure is included in the IC package according to any one of examples 28-31.
Example 33 provides a computing device according to example 32, where the computing device is a wearable or handheld computing device.
Example 34 provides a computing device according to examples 32 or 33, where the computing device further includes one or more communication chips.
Example 35 provides a computing device according to any one of examples 32-34, where the computing device further includes an antenna.
Example 36 provides a computing device according to any one of examples 32-35, where the carrier substrate is a motherboard.
Example 37 provides a method of fabricating an IC structure, the method including providing a preliminary IC structure including a stack of nanoribbons and a region of a doped semiconductor material in the stack of nanoribbons; providing a first liner including a sacrificial material over exposed surfaces of the region (e.g., including over a top and over a bottom of the region); providing a second liner including a first insulator material over the first liner; providing a second insulator material around the region including the first liner and the second liner, forming an opening in the second insulator material over the region; removing a portion of the second liner exposed in the opening; removing the first liner, where removal of the first liner forms a void between the region and the second liner; providing an interface material on the region in the void; and providing a contact structure including a conductive material on the interface material in the void.
Example 38 provides the method of example 37, where: the sacrificial material includes a third insulator material that is different from the first insulator material.
Example 39 provides the method of examples 37 or 38, where: removing the first liner includes isotropically etching the sacrificial material.
Example 40 provides the method of any one of examples 37-39, where: providing the preliminary IC structure includes providing alternate layers of a semiconductor material and a further material, and forming a fin from the alternate layers of the semiconductor material and the further material; forming openings in the fin; and providing a semiconductor material in the openings.
Example 41 provides the method of any one of examples 37-40, where: the region is a first region, the stack of nanoribbons is a first stack of nanoribbons, and where the preliminary IC structure includes a second stack of nanoribbons and a second region in the second stack of nanoribbons; and the method further includes providing a third liner including the sacrificial material over exposed surfaces of the second region (e.g., including over a top and over a bottom of the second region); providing a fourth liner including the first insulator material over the third liner; and providing the second insulator material around the second region including the third liner and the fourth liner.
Example 42 provides the method of example 41, where: the contact structure is a first contact structure provided from a first side of the preliminary IC structure; and the method further includes flipping over the preliminary IC structure to expose a second side of the IC structure; forming a second opening over the second region from the second side; removing a portion of the fourth liner exposed in the second opening; removing the third liner, where removal of the third liner forms a second void between the region and the third liner; providing the interface material on the second region in the second void; and providing a second contact structure including the conductive material on the interface material in the second void.
Example 43 provides a method according to any one of examples 37-42, where the IC structure is an IC structure according to any one of the preceding examples.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize. These modifications may be made to the disclosure in light of the above detailed description.

1. An integrated circuit (IC) structure, comprising:
a region of a doped semiconductor material;
a stack of nanoribbons of a semiconductor material including first portions and second portions on either side of the region, wherein the first portions are in contact with a first side of the region and the second portions are in contact with a second side of the region; and
a conductive material over a portion of the region between the first side and the second side in a same layer as at least one of the nanoribbons of the stack.

2. The IC structure of claim 1, wherein:
the stack of nanoribbons includes a bottom nanoribbon and a top nanoribbon stacked over the bottom nanoribbon; and
the conductive material is a continuous conductive material over the portions of the region in same layers as the top nanoribbon and the bottom nanoribbon.

3. The IC structure of claim 1, wherein:
the conductive material is a continuous conductive material over the portions of the region in layers above and below the nanoribbons of the stack.

4. The IC structure of claim 1, wherein:
the conductive material is a continuous conductive material that wraps around the region.

5. The IC structure of claim 1, further comprising:
an interface material between the doped semiconductor material and the conductive material.

6. The IC structure of claim 5, wherein:
the interface material is a continuous interface material that wraps around the region.

7. The IC structure of claim 1, further comprising:
a liner including an insulator material over the conductive material.

8. The IC structure of claim 7, wherein:
the liner includes a continuous insulator material that wraps around the region.

9. The IC structure of claim 7, wherein:
a thickness of the conductive material between the liner and the region is in a range of 3-15 nanometers.

10. The IC structure of claim 1, further comprising:
a contact structure including:
a first portion of the conductive material in a layer over the stack of nanoribbons, and a second portion that includes the conductive material over the portions of the region, wherein the second portion wraps around the region and is in contact with the first portion.

11. An integrated circuit (IC) structure, comprising:
a stack of nanoribbons, wherein the stack includes a first nanoribbon in a first plane and a second nanoribbon in a second plane over the first nanoribbon, and wherein the nanoribbons include first channel regions of a first transistor and second channel regions of a second transistor;
a region including a continuous doped semiconductor material between the first channel regions and the second channel regions, wherein the region includes a first portion in the first plane and a second portion in the second plane; and
a contact structure coupled with the region, wherein the contact structure includes a continuous layer of conductive material over the first portion and over the second portion of the region.

12. The IC structure of claim 11, wherein:
the region includes a third portion in a third plane under the nanoribbons of the stack and a fourth portion in a fourth plane over the nanoribbons of the stack; and
the continuous layer of conductive material is over the third portion and over the fourth portion.

13. The IC structure of claim 11, wherein:
the continuous layer of conductive material wraps around the region between the first channel regions and the second channel regions.

14. The IC structure of claim 11, further comprising:
a layer of interface material between the region and the continuous layer of conductive material.

15. The IC structure of claim 14, wherein:
the interface material is a continuous interface material that wraps around the region between the first channel regions and the second channel regions.

16. The IC structure of claim 11, further comprising:
a first insulator material surrounding the first portion and the second portion of the region; and
a layer of a second insulator material between the first insulator material and the continuous layer of conductive material.

17. The IC structure of claim 16, wherein:
the layer of the second insulator material is a continuous layer of the second insulator material that wraps around the region between the first channel regions and the second channel regions.

18. The IC structure of claim 11, wherein:
the contact structure includes a conductive structure in a layer over the stack of nanoribbons, wherein the conductive structure is in contact with the continuous layer of conductive material.

19. An integrated circuit (IC) structure, comprising:
a stack of nanoribbons of a semiconductor material;
a region in the stack of nanoribbons that is either a source region or a drain region of a transistor, wherein the region includes first portions in contact with the semiconductor material of the nanoribbons on either side of the region, and second portions between the first portions; and
a continuous conductive material lining the second portions of the region.

20. The IC structure of claim 19, further comprising:
a continuous interface material lining the second portions of the region between the continuous conductive material and the region.
